(19) United States
(12) Patent Application Publication
(10) Pub. No.: US 2005/0093593 A1
(43) Pub. Date: May 5, 2005

(54) Clock generation system applicable to PLL

(75) Inventors: Fumitaka Fukuzawa, Tokyo (JP); Koichi Ishimi, Tokyo (JP)

Correspondence Address: McDERMOTT, WILL & EMERY, 600 13th Street, N.W., WASHINGTON, DC, 20005-3096, US

(73) Assignee: RENESAS TECHNOLOGY CORP.

(21) Appl. No.: 10/973,450

(22) Filed: Oct. 27, 2004

(30) Foreign Application Priority Data
Oct. 31, 2003 (JP) JP2003-372113

(51) Int. Cl. H03L 7/06

(52) U.S. Cl. 327/156

(57) ABSTRACT

A technique for generating an appropriate clock is provided. A clock generation circuit generates a logic-circuit clock on the basis of a reference clock and outputs the logic-circuit clock to a logic circuit. The clock generation circuit and the logic circuit are both supplied with power from a power supplier. According to a control signal from a power controller, the power supplier changes a power voltage value provided to the clock generation circuit and the logic circuit. The control signal is generated by the power controller on the basis of a counter value from the clock generation circuit. The counter value is obtained from a digital counter which determines the delay speeds of delay elements in a multiplier circuit in the clock generation circuit.

### BACKGROUND OF THE INVENTION

1. Field of the Invention

The present invention relates to a technique for generating clocks and is applicable to, for example, digital PLLs (phase locked loops) and analog PLLs.

2. Description of the Background Art

Conventionally, analog PLL circuits and digital PLL circuits have been proposed as means for generating clocks, adopted for the operations of a semiconductor integrated circuit. One of such digital PLL circuits is introduced, for example in Japanese Patent Application Laid-open No. 2000-244309.

Also, techniques for controlling power voltages or currents by using a voltage provided for controlling a VCO (voltage-controlled oscillator) in analog PLL circuits are introduced in Japanese Patent Application Laid-open Nos. 2002-73181, 8-44465 (1996) and 2000-3234.

The operating speed of a semiconductor integrated circuit varies according to variations in device characteristics in circuit manufacture and according to usage conditions such as temperature, voltage and frequency. To ensure normal operation of the circuit even in the presence of such variations, clocks are designed with an enough margin. This may, however, result in overspecification for normal use. For example, there is the problem that the application of a power voltage than is necessary may result in excessive power consumption, which may further result in a noise increase. Also, there is a possibility of malfunctions depending on some change in the usage conditions.

### SUMMARY OF THE INVENTION

The present invention has been made in view of the aforementioned problems, and has an object to provide a technique for generating an appropriate clock.

A first clock generation system according to the present invention includes a multiplier circuit including a ring oscillator and a control circuit; and a power supplier for supplying operating power to the multiplier circuit. The ring oscillator includes a delay element and a logic gate, and outputs an output clock signal from the logic gate. A delay amount of the delay element is controlled based on a digital value. The logic gate performs a logical operation upon an output of the delay element. The control circuit controls an operation of the logic gate and the digital value on the basis of a phase difference between the output of the delay element and a reference clock signal. A parameter of the operating power is controlled based on the digital value.

By controlling the parameter of the operating power, it is possible, in the case of a wide operating margin, to reduce power consumption and noise without degradation of desired performance, and it is possible, in the case of a small operating margin, to prevent the occurrence of malfunctions. In this way, the parameter of the operating power can be controlled appropriately for variations in device manufacturing and in usage environment. This eliminates the need to allow for excess margin in circuit design and hence allows the design of a circuit that is fast, small, and consumes little electricity.

A second clock generation system according to the present invention includes a ring oscillator and a control circuit. The ring oscillator includes a delay element and a logic gate, and outputs an output clock signal from the logic gate. A delay amount of the delay element is controlled based on a digital value. The logic gate performs a logical operation upon an output of the delay element. The control circuit controls an operation of the logic gate and the digital value on the basis of a phase difference between the output of the delay element and a reference clock signal. A frequency of the output clock signal is controlled based on the digital value.

In the case of a wide operating margin, control is exercised to increase the frequency, thereby allowing a circuit which is supplied with the output clock signal to operate with higher efficiency than required. In the case of a small operating margin, control is exercised to decrease the frequency, thereby preventing the occurrence of malfunctions in a circuit supplied with the output clock signal.

A third clock generation system according to the present invention includes a multiplier circuit including a ring oscillator and a control circuit; and a frequency divider circuit. The ring oscillator includes a delay element and a logic gate, and outputs an output clock signal from the logic gate. A delay amount of the delay element is controlled based on a digital value. The logic gate performs a logical operation upon an output of the delay element. The control circuit controls an operation of the logic gate and the digital value on the basis of a phase difference between the output of the delay element and a reference clock signal. The frequency divider circuit frequency-divides the output clock signal. Either or both of a division ratio in the frequency divider circuit and a multiplication ratio in the multiplier circuit are controlled based on the digital value.

In the case of a wide operating margin, control is exercised to increase the frequency, thereby allowing a circuit which is supplied with the output clock signal to operate with higher efficiency than required. In the case of a small operating margin, control is exercised to decrease the frequency, thereby preventing the occurrence of malfunctions in a circuit supplied with the output clock signal.

A fourth clock generation system according to the present invention includes a clock generation circuit and a power supplier. The clock generation circuit includes a voltage-controlled oscillator, a phase comparator, and a loop filter. An oscillation frequency in the voltage-controlled oscillator is controlled based on a control voltage. The phase comparator compares phases of a reference clock signal and a frequency-divided clock which is obtained by frequency-dividing an output of the voltage-controlled oscillator. The loop filter outputs the control voltage on the basis of an output of the phase comparator. The power supplier supplies operating power to the clock generation circuit. A parameter of the operating power is controlled based on a value of the control voltage.

By determining and storing an appropriate parameter of power supply for a semiconductor integrated circuit during manufacturing test, even if there exists an individual difference depending on variations in the manufacture of semiconductor integrated circuits, a subsequent power supply can be made with an appropriate parameter for individual semiconductor integrated circuits. Also, it is easy, by using the parameter, to classify the products according to the performance of the semiconductor integrated circuit.

A fifth clock generation system according to the present invention includes a clock generation circuit. The clock generation circuit includes a voltage-controlled oscillator, a phase comparator, and a loop filter. An oscillation frequency in the voltage-controlled oscillator is controlled based on a control voltage. The phase comparator compares phases of a reference clock signal and a frequency-divided clock which is obtained by frequency-dividing an output of the voltage-controlled oscillator. The loop filter outputs the control voltage on the basis of an output of the phase comparator. The clock generation system generates an output clock signal having a frequency which is controlled based on the control voltage.

In the case of a wide operating margin, control is exercised to increase the frequency, thereby allowing a circuit which is supplied with the output clock to operate with higher efficiency than required. In the case of a small operating margin, control is exercised to decrease the frequency, thereby preventing the occurrence of malfunctions in a circuit supplied with the output clock.

A sixth clock generation system according to the present invention includes an analog PLL circuit and a frequency divider circuit. The analog PLL circuit includes a voltage-controlled oscillator, a phase comparator, and a loop filter. An oscillation frequency in the voltage-controlled oscillator is controlled based on a control voltage. The phase comparator compares phase of a reference clock signal and a frequency-divided clock which is obtained by frequency-dividing an output of the voltage-controlled oscillator. The loop filter outputs the control voltage on the basis of an output of the phase comparator. The frequency divider circuit frequency-divides an output of the voltage-controlled oscillator. Either or both of a division ratio in the frequency divider circuit and a division ratio in the analog PLL circuit are controlled based on the control voltage.

In the case of a wide operating margin, control is exercised to increase the frequency, thereby allowing a circuit which is supplied with the output clock to operate with higher efficiency than required. In the case of a small operating margin, control is exercised to decrease the frequency, thereby preventing the occurrence of malfunctions in a circuit supplied with the output clock.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram illustrating a configuration according to a first preferred embodiment of the present invention;

FIG. 2 is a block diagram illustrating a configuration of a clock generation circuit 1;

FIG. 3 is a block diagram illustrating a configuration of a multiplier circuit 11;

FIG. 4 is a timing chart illustrating multiplication by a multiplication ratio of 4;

FIG. 5 is a block diagram illustrating a configuration of a phase synchronizing circuit 12;

FIG. 6 is a timing chart showing synchronization of clocks;

FIG. 7 is a flow chart illustrating an operation according to the first preferred embodiment of the present invention;

FIG. 8 is a flow chart illustrating an operation according to a modification of the first preferred embodiment of the present invention;

FIG. 9 is a block diagram illustrating a configuration according to a second preferred embodiment of the present invention;

FIG. 10 is a flow chart illustrating an operation according to the second preferred embodiment of the present invention;

FIG. 11 is a flow chart illustrating power supply using a stored power-voltage control value;

FIG. 12 is a block diagram illustrating a configuration according to a third preferred embodiment of the present invention;

FIG. 13 is a block diagram illustrating a configuration according to a fourth preferred embodiment of the present invention;

FIG. 14 is a flow chart illustrating a first operation according to a fifth preferred embodiment of the present invention;

FIG. 15 is a flow chart illustrating a modification of the first operation according to the fifth preferred embodiment of the present invention;

FIGS. 16 and 17 are flow charts illustrating a second operation according to the fifth preferred embodiment of the present invention;

FIG. 18 is a block diagram illustrating a configuration according to a sixth preferred embodiment of the present invention;

FIG. 19 is a block diagram illustrating a configuration of the clock generation circuit 1;

FIG. 20 is a flow chart illustrating an operation according to the sixth preferred embodiment of the present invention;

FIG. 21 is a flow chart illustrating an operation according to a modification of the sixth preferred embodiment of the present invention;

FIG. 22 is a block diagram illustrating a configuration according to a seventh preferred embodiment of the present invention;

FIG. 23 is a flow chart illustrating an operation according to the seventh preferred embodiment of the present invention;

FIG. 24 is a flow chart illustrating power supply using a stored frequency control value;

FIG. 25 is a block diagram illustrating a configuration according to an eighth preferred embodiment of the present invention;

FIG. 26 is a block diagram illustrating a configuration according to a ninth preferred embodiment of the present invention;

FIG. 27 is a block diagram illustrating a configuration according to a tenth preferred embodiment of the present invention;

FIG. 28 is a block diagram illustrating a configuration of a clock generation circuit 10;

FIG. 29 is a flow chart illustrating a first operation according to the tenth preferred embodiment of the present invention;

FIG. 30 is a flow chart illustrating a second operation according to the tenth preferred embodiment of the present invention;

FIG. 31 is a flow chart illustrating a third operation according to the tenth preferred embodiment;

FIG. 32 is a flow chart illustrating a fourth operation according to the tenth preferred embodiment;

FIG. 33 is a block diagram illustrating a configuration according to an eleventh preferred embodiment of the present invention;

FIG. 34 is a flow chart illustrating a first operation according to the eleventh preferred embodiment of the present invention;

FIG. 35 is a flow chart illustrating a second operation according to the eleventh preferred embodiment of the present invention;

FIG. 36 is a block diagram illustrating a configuration according to a twelfth preferred embodiment of the present invention;

FIG. 37 is a block diagram illustrating a configuration according to a thirteenth preferred embodiment of the present invention;

FIG. 38 is a block diagram illustrating a configuration according to a fourteenth preferred embodiment of the present invention;

FIG. 39 is a block diagram illustrating a configuration of the clock generation circuit 10;

FIG. 40 is a flow chart illustrating an operation according to the fourteenth preferred embodiment of the present invention;

FIG. 41 is a flow chart illustrating an operation according to a modification of the fourteenth preferred embodiment;

FIG. 42 is a block diagram illustrating a configuration according to a fifteenth preferred embodiment of the present invention;

FIG. 43 is a flow chart illustrating an operation according to the fifteenth preferred embodiment of the present invention;

FIG. 44 is a block diagram illustrating a configuration according to a sixteenth preferred embodiment of the present invention; and

FIG. 45 is a block diagram illustrating a configuration according to a seventeenth preferred embodiment of the present invention.

### DESCRIPTION OF THE PREFERRED EMBODIMENTS

A. Application to Digital PLL

First Preferred Embodiment

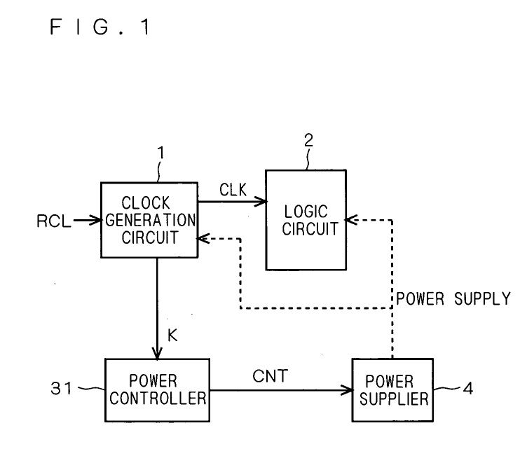

FIG. 1 is a block diagram illustrating a configuration to which a clock generation technique according to a first preferred embodiment of the present invention is applicable. A clock generation circuit 1 generates a logic-circuit clock CLK on the basis of a reference clock RCL and outputs the clock CLK to a logic circuit 2. The clock generation circuit 1 and the logic circuit 2 are formed, for example on the same semiconductor substrate and both circuits are supplied with power from a power supplier 4. The power supplier 4 changes a power voltage value provided to the clock generation circuit 1 and the logic circuit 2, according to a control signal CNT from a power controller 31. The power supplier 4 and the power controller 31 may be provided within the same semiconductor integrated circuit as the clock generation circuit 1 and the logic circuit 2, or they may be provided outside the integrated circuit.

The control signal CNT is generated by the power controller 31 on the basis of a counter value K obtained from the clock generation circuit 1.

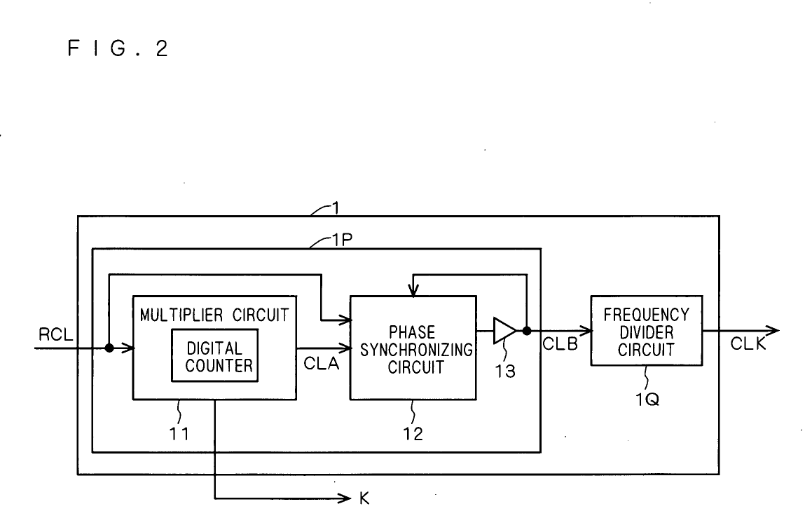

FIG. 2 is a block diagram illustrating a configuration of the clock generation circuit 1. The clock generation circuit 1 includes a digital PLL circuit 1P and a frequency divider circuit 1Q.

The digital PLL circuit 1P includes a multiplier circuit 11, a phase synchronizing circuit 12, and a buffer 13. The multiplier circuit 11 inputs the reference clock RCL and outputs a first clock CLA and the counter value K. The counter value K is the counter value of a digital counter in the multiplier circuit 11, later to be described. The phase synchronizing circuit 12 synchronizes the phases of the reference clock RCL and the first clock CLA to provide an output. The buffer 13 buffers the output of the phase synchronizing circuit 12 to output as a second clock CLB. The second clock CLB is returned to the phase synchronizing circuit 12 and is also given to the frequency divider circuit 1Q.

The frequency divider circuit 1Q frequency-divides the second clock CLB by a predetermined division ratio to generate and output the logic-circuit clock CLK.

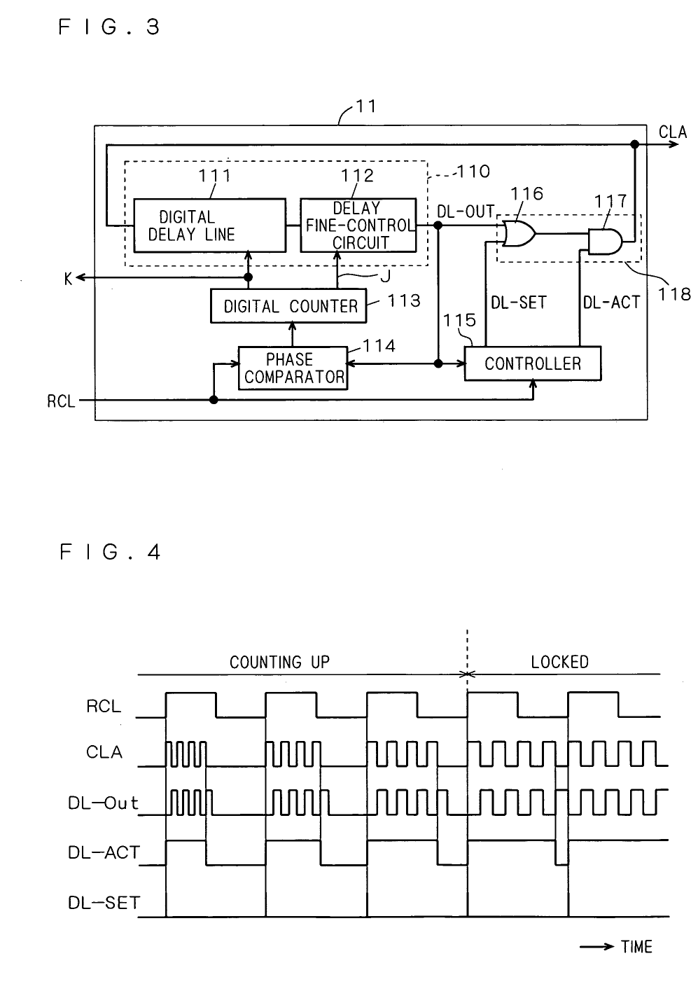

FIG. 3 is a block diagram illustrating a configuration of the multiplier circuit 11. The multiplier circuit 11 multiplies the reference clock RCL by a predetermined multiplication ratio to generate and output the first clock CLA.

The multiplier circuit 11 includes a ring oscillator which includes a delay circuit 110 and a logic gate 118. The logic gate 118 includes, for example, an OR gate 116 and an AND gate 117.

An output DL-Out of the delay circuit 110, together with a control signal DL-SET, is fed to the OR gate 116, which outputs the logical OR of the output DL-Out and the control signal DL-SET. The output of the OR gate 116, together with a control signal DL-ACT, is fed to the AND gate 117, which outputs the logical AND of the output of the OR gate 116 and the control signal DL-ACT, as the first clock CLA.

The multiplier circuit 11 further includes a controller 115, which generates the control signals DL-ACT and DL-SET on the basis of the output DL-Out and the reference clock RCL.

The multiplier circuit 11 further includes a phase comparator 114, which compares the phases of the output DL-Out and the reference clock RCL.

The multiplier circuit 11 further includes a digital counter 113. The digital counter 113 increments or decrements its counter values K and J on the basis of a phase difference, obtained by the phase comparator 114, between the output DL-Out and the reference clock RCL, or more specifically a phase difference between the falling edge of the output DL-Out and the rising edge of the reference clock RCL.

The counter values K and J are respectively higher-order and lower-order bits of the counter value of the digital counter as a whole. The delay circuit 110 includes a digital delay line 111 and a delay fine-control circuit 112, which are connected for example in series and the delay amounts of which are increased or decreased according respectively to the counter values K and J.

FIG. 4 is a timing chart showing the behavior of each signal when the first clock CLA is multiplied into four times the reference clock RCL. This figure illustrates the case where the first clock CLA is multiplied in phase with the reference clock RCL by increasing the delay amount of the delay circuit 110.

With the rising edge of the reference clock RCL, the controller 115 asserts the control signal DL-SET with a small pulse width. Thereby, the output of the OR gate 116 forcefully becomes high (“H”). The controller 115 also asserts the control signal DL-ACT with the rising edge of the reference clock RCL and negates this signal DL-ACT with the N-th (N is a positive integer) rising edge of the output DL-Out. The positive integer N is a multiplication ratio, which is 4 in this case but which may instead be 1, for example.

Since the output of the AND gate 117 is forcefully low (“L”) during negation of the control signal DL-ACT, the first clock CLA has four pulse waveforms in one cycle of the reference clock RCL.

This pulse width increases with increasing delay amount of the delay circuit 110. Thus, the pulse width of the first clock CLA is increased by incrementing the counter values K and J of the digital counter 113. However, when the phase difference between the falling edge of the output DL-Out and the rising edge of the reference clock RCL becomes zero, the phase comparator 114 stops the digital counter 113 from incrementing its counter values. In this way, an increase in the delay amount of the delay circuit 110 is stopped, and the first clock CLA which has been multiplied into four times the reference clock RCL is brought into a locked condition.

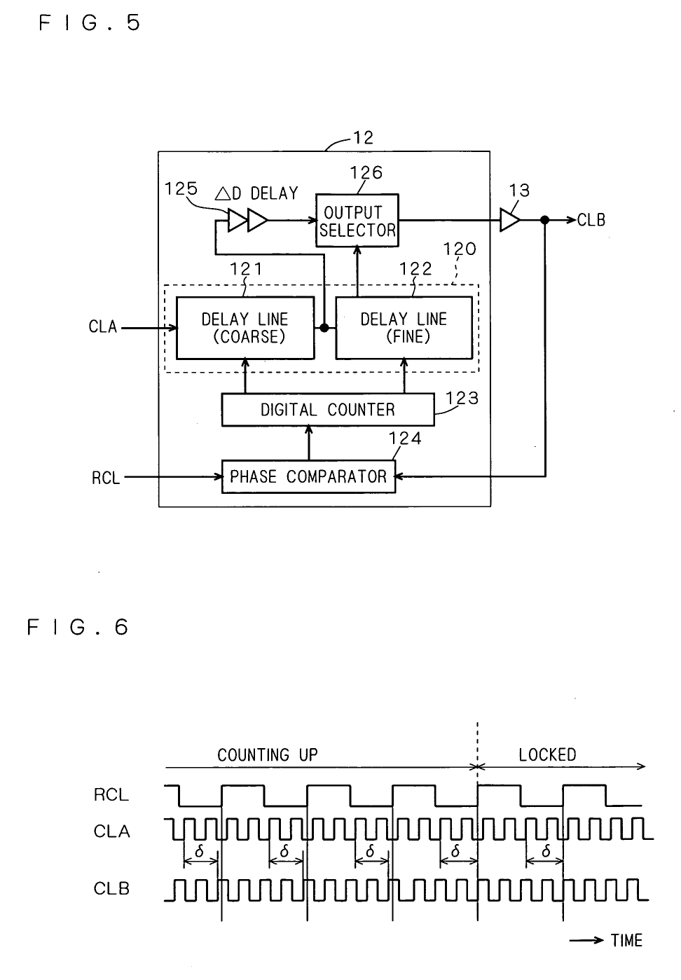

FIG. 5 is a block diagram illustrating a configuration of the phase synchronizing circuit 12. The phase synchronizing circuit 12 includes delay circuits 120 and 125 which perform delay processing on the first clock CLA.

More specifically, the delay circuit 120 includes a coarse-control delay line (shown as “COARSE” in FIG. 5) 121 and a fine-control delay line (shown as “FINE” in FIG. 5) 122 which are connected in series. The delay circuit 125 delays the output of the coarse-control delay line 121.

The phase synchronizing circuit 12 further includes an output selector 126, which selects either the first clock CLA that is delayed by the coarse-control delay line 121 and the fine-control delay line 122, or the first clock CLA that is delayed by the coarse-control delay line 121 and the delay circuit 125. The selected clock is provided to the buffer 13.

The phase synchronizing circuit 12 further includes a digital counter 123 and a phase comparator 124. The phase comparator 124 compares the phases of the reference clock RCL and the second clock CLB to control the counter value of the digital counter 123 according to the phase difference. The counter value of the digital counter 123 is used to control the delay amounts of the coarse-control delay line 121 and of the fine-control delay line 122.

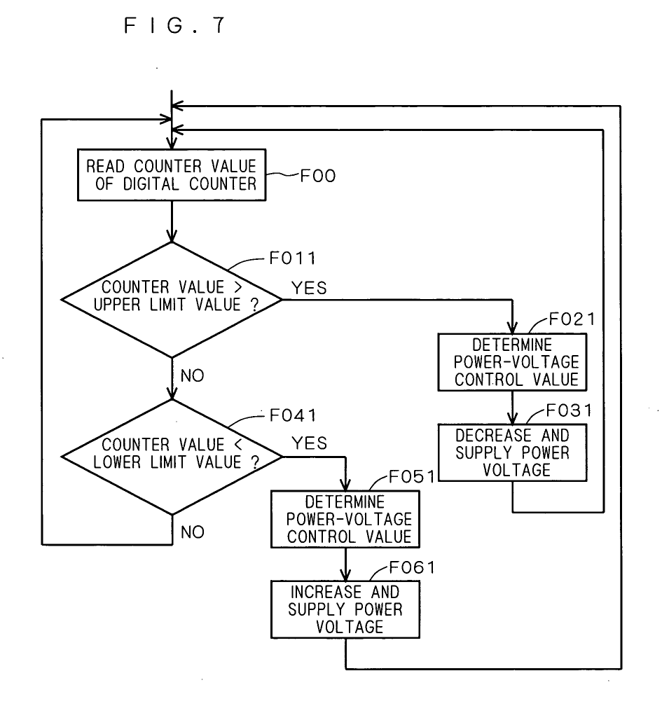

FIG. 6 is a timing chart showing the behavior of each signal when the second clock CLB is synchronized with the reference clock RCL. Due to the delay processing performed on the first clock CLA by the phase synchronizing circuit 12 and due to delay by the buffer 13, the second clock CLB is delayed by a delay amount δ relative to the first clock CLA. The delay amount δ increases with increasing counter value of the digital counter 123. When the phase difference between the rising edge of the reference clock RCL and the rising edge of the second clock CLB becomes zero, the phase comparator 124 stops the digital counter 123 from incrementing its counter value. In this way, an increase in the delay amount of the delay circuit 120 is stopped and the second clock CLB which has been multiplied into four times the reference clock RCL is brought into a locked condition.

Now, the digital delay line 111 causes the first clock CLA to pass through as many unit delay elements as a specified number of stages given by the counter value K. The operating speeds of semiconductor devices forming those unit delay elements, e.g., the operating speeds of transistors, vary according to manufacturing variations and usage conditions such as temperature and power voltage. That is, even if the pulse width of the first clock CLA is the same, the counter value K at which the digital PLL circuit 1P is in a stable condition varies according to the above manufacturing variations and usage conditions.

As the unit delay elements have better characteristics within manufacturing variations, as the temperature is decreased and as the power voltage is increased, the processing speeds of the unit delay elements are increased and accordingly the counter value K is incremented. On the contrary, as the unit delay elements have poorer characteristics, as the temperature is increased and as the power voltage is decreased, the processing speeds of the unit delay elements are decreased and accordingly the counter value K is decremented.

From the above, in the former case, control is exercised to lower the power voltage, thereby allowing reductions in power consumption and noise without degradation of desired performance. In the latter case, control is exercised to increase the power voltage, thereby preventing the occurrence of malfunctions.

This advantage is especially remarkable in the case where a circuit, such as the logic circuit 2, which includes a great number of semiconductor devices (e.g., transistors) is formed on the same semiconductor substrate as the clock generation circuit 1. This is because, since semiconductor devices forming the clock generation circuit 1 and the logic circuit 2 are formed on the same semiconductor substrate, they are believed to show mutually similar characteristics relative to the usage environment such as temperature; and therefore, it is possible in the logic circuit 2 to reduce power consumption and noise and to prevent the occurrence of malfunctions.

FIG. 7 is a flow chart illustrating an operation according to the first preferred embodiment of the present invention, the operation being performed with the digital PLL circuit 1P being in a locked condition. Whether the digital PLL circuit 1P is locked can be detected by the phase comparator 114 determining that the phase difference between the falling edge of the output DL-Out and the rising edge of the reference clock RCL is zero.

When the phase comparator 114 determines that the phase difference between the falling edge of the output DL-Out and the rising edge of the reference clock RCL is zero, and thereby when the digital counter 113 stops changing its counter values, the counter value K of the digital counter 113 is read out into the power controller 31 in step F00 (see FIG. 1). Here, not only the counter value K, but also the counter value J may be read out and put to use in the following processing.

The process then proceeds to step F011 where the power controller 31 determines whether or not the counter value K (or the counter values K and J; the same is true for any of the following flow charts) is greater than an upper limit value. If the result of the determination is positive, that is, if the counter value K is greater than the upper limit value, the process goes through the processing of steps F021 and F031 and returns to step F00. If the result of the determination is negative, that is, if the counter value K is equal to or smaller than the upper limit value, the process proceeds to step F041 without going through the processing of steps F021 and F031.

In step F041, the power controller 31 determines whether or not the counter value K is smaller than a lower limit value. If the result of the determination is positive, that is, if the counter value K is smaller than the lower limit value, the process goes through the processing of steps F051 and F061 and returns to step F00. If the result of the determination is negative, that is, if the counter value K is equal to or greater than the lower limit value, the process returns to step F00 without going through the processing of steps F051 and F061.

From the above description, it is found that the process is divided into three branches of processing according to the magnitude of the counter value K. The first branch applies to the case where the counter value K is not less than the lower limit value and is not more than the upper limit value, in which case the power controller 31 does not perform processing that depends on the magnitude of the counter value K. The second branch applies to the case where the counter value K is greater than the upper limit value, in which case the process of decreasing the power voltage is performed. The third branch applies to the case where the counter value K is smaller than the lower limit value, in which case the process of increasing the power voltage is performed.

The process of decreasing the power voltage is performed in the aforementioned steps F021 and F031. More specifically, in step F021, the power controller 31 determines a power-voltage control value, which is one of parameters of operating power, according to the extent to which the counter value K exceeds the upper limit value. Then, control information CNT including the power-voltage control value is provided to the power supplier 4. In step F031, the power supplier 4 supplies power at a lower power voltage than before to the clock generation circuit 1 and the logic circuit 2.

The process of increasing the power voltage is performed in the aforementioned steps F051 and F061. More specifically, in step F051, the power controller 31 determines the power-voltage control value according to the extent to which the counter value K is less than the lower limit value. Then, the control information CNT including the power-voltage control value is given to the power supplier 4. In step F061, the power supplier 4 supplies power at a greater power voltage than before to the clock generation circuit 1 and the logic circuit 2.

In steps F021 and F051, it is desirable that the power-voltage control value be determined within the range where the digital PLL circuit 1P can be locked at a desired frequency. This is in order to generate the logic-circuit clock CLK having a stable frequency.

When the process returns to step F00 from any of steps F041, F061, and F031, a predetermined time interval (e.g., a predetermined clock cycle) may be waited before the execution of step F00. This is because there is considered to be little need to change the power voltage within a short time.

By the aforementioned process, in the case of a wide operating margin, it is possible, by decreasing the power voltage, to reduce power consumption and noise without degradation of desired performance. In the case of a small operating margin, it is possible, by increasing the power voltage, to prevent the occurrence of malfunctions.

In this way, the power voltage provided to the clock generation circuit 1 and the logic circuit 2 can be controlled to an appropriate value for variations in device manufacturing and in the usage environment. This further eliminates the need to allow for excess margin in circuit design and hence allows the design of a circuit that is fast, small, and consumes little electricity.

It is noted that the power-voltage control value may not necessarily be updated regularly. For example if the power-voltage control value is once determined at the start of the supply of operating power to a semiconductor integrated circuit which includes the clock generation circuit 1 and the logic circuit 2, the power voltage may be fixed thereafter.

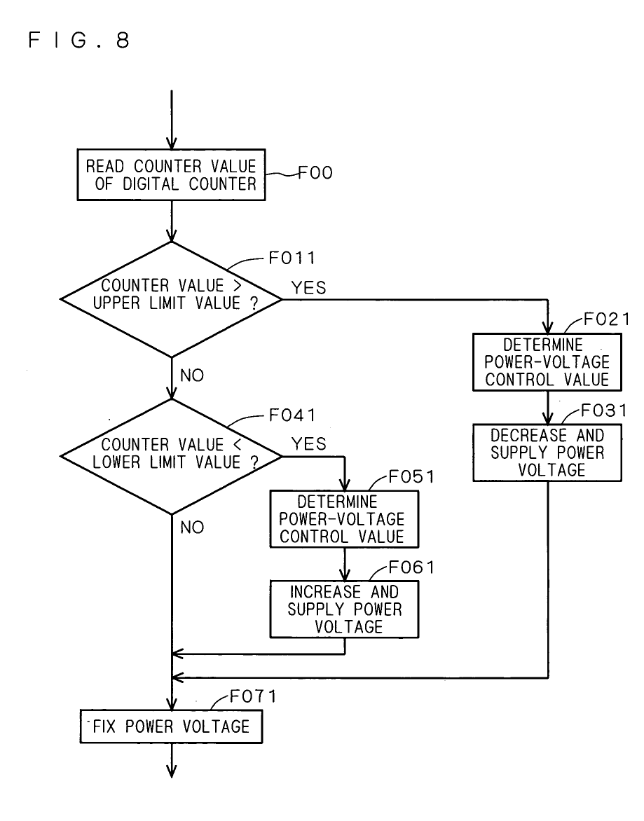

FIG. 8 is a flow chart illustrating an operation according to the above modification. The flow chart is such that modifications are made to the processing of the cases where the result of the determination is negative in step F041, where the processing of step F031 is completed, and where the processing of step F061 is completed, in the flow chart of FIG. 7. Similarly in the flow chart of FIG. 7, the processing of step F00 is started after the digital PLL circuit 1P is locked.

More specifically, although in the flow chart of FIG. 7 the process in any of the aforementioned cases returns to step F00 to set a new power voltage, the process in the flow chart of FIG. 8 proceeds to step F071 to fix the power voltage which is then supplied. The power-voltage control value will not be updated, and thus the power voltage will remain fixed, until the application of power to the aforementioned semiconductor integrated circuit is cut off.

Also, in some cases, it is not always necessary to bring the reference clock RCL and the logic-circuit clock CLK exactly in phase with each other. In that case, the phase synchronizing circuit 12 and the buffer 13 may be omitted from FIG. 2, in which case the first clock CLA is given as-is as the second clock CLB to the frequency divider circuit 1Q.

Second Preferred Embodiment

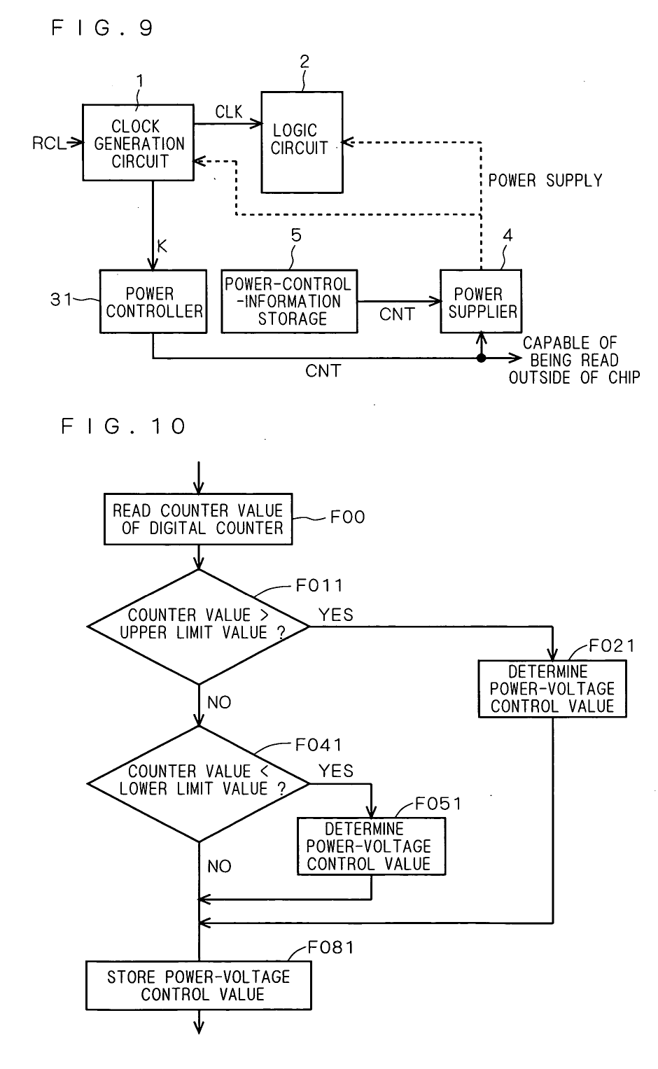

FIG. 9 is a block diagram illustrating a configuration to which a clock generation technique according to a second preferred embodiment of the present invention is applicable. The configuration is such that a power-control-information storage 5 is added to the configuration of the first preferred embodiment shown in FIG. 1. Therein, the power supplier 4 supplies power to the clock generation circuit 1 and the logic circuit 2 at a voltage value based on the control signal CNT obtained from the power controller 31.

For example, the clock generation circuit 1, the logic circuit 2, the power controller 31, the power supplier 4, and the power-control-information storage 5 are formed within a chip. The control signal CNT is capable of being read outside of the chip. During testing, a tester is connected to the chip to read out and store the control signal CNT. In shipments of chips, the control signal CNT stored in the tester is stored in the power-control-information storage 5.

The power-control-information storage 5 can be implemented by using a non-volatile memory such as a flash memory; or a laser-trimmed memory.

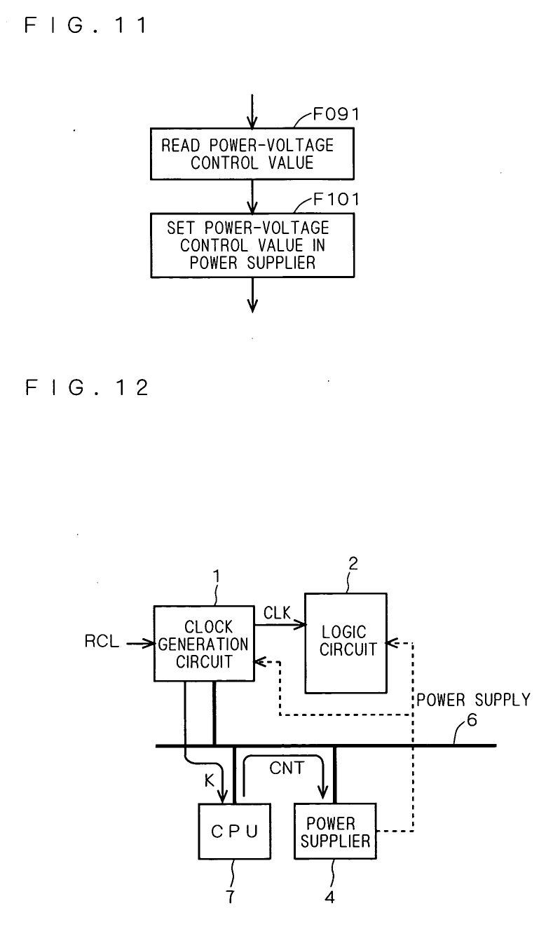

FIG. 10 is a flow chart illustrating an operation according to the second preferred embodiment of the present invention. As compared with the flow chart of FIG. 8, this flow chart is such that step F071 is replaced by step F081 and the processing of steps F031 and F061 is omitted. In step F081, the power-control-information storage 5 stores the power-voltage control value. In this flow chart, also, the processing of step F00 is started after the digital PLL circuit 1P is locked.

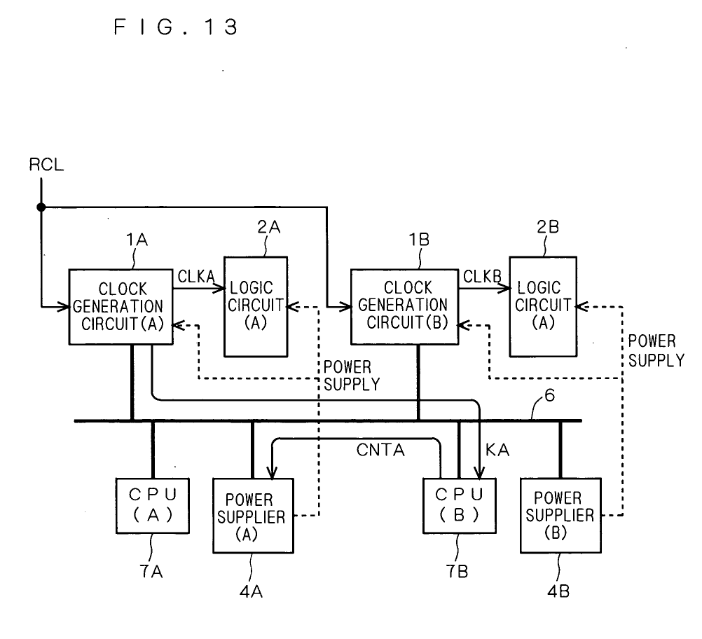

FIG. 11 is a flow chart illustrating power supply using the power-voltage control value stored in the power-control-information storage 5. The power-voltage control value is read out of the power-control-information storage 5 in step F091 and is set in the power supplier 4 in step F101. Thereby, power supply to the clock generation circuit 1 and the logic circuit 2 can be made with an appropriate voltage value, on the basis of the stored power-voltage control value.

The flow chart of FIG. 10 is applicable to, for example, manufacturing test of the semiconductor integrated circuit including the clock generation circuit 1 and the logic circuit 2. During the manufacturing test, a power voltage appropriate for the semiconductor integrated circuit is determined and stored in the power-control-information storage 5. Thereby, even if there exists an individual difference depending on variations in the manufacture of semiconductor integrated circuits, a subsequent power supply can be made with an appropriate voltage value for individual semiconductor integrated circuits.

There is also the advantage that, because the power-voltage control value obtained by execution of the flow chart of FIG. 10 is stored in the power-control-information storage 5, it is easy, by using the power-voltage control value, to classify the products according to the performance of the semiconductor integrated circuit.

Although the power voltage is once fixed, it is of course desirable to use simultaneously the technique described in the first preferred embodiment in order to obtain an appropriate voltage value for the usage environment such as temperature. For use in combination with the technique described in the first preferred embodiment, the configuration illustrated in FIG. 9 includes a path over which the control signal CNT is directly given to the power supplier 4.

Third Preferred Embodiment

In this preferred embodiment, the function performed by the power controller 31 in the first preferred embodiment is performed by a CPU (central processing unit).

FIG. 12 is a block diagram illustrating a configuration to which a clock generation technique according to a third preferred embodiment of the present invention is applicable. As compared with the configuration of the first preferred embodiment shown in FIG. 1, this configuration is such that the power controller 31 is replaced by a CPU 7 and the clock generation circuit 1 (especially the multiplier circuit 11) and the power supplier 4 are connected to the CPU 7 through a bus 6. Like the power controller 31 and the power supplier 4, the CPU 7 may be provided within the same semiconductor integrated circuit as the clock generation circuit 1 and the logic circuit 2, or it may be provided outside the integrated circuit.

Similar to the first preferred embodiment, this preferred embodiment also permits the operations illustrated in the flow charts of FIGS. 7 and 8. More specifically, the counter value K which is read out in step F00 is provided through the bus 6 to the CPU 7, which performs the processing of steps F021 and F051. Then, the control signal CNT is given from the CPU 7 to the power supplier 4 through the bus 6.

According to this preferred embodiment, since the CPU 7 determines the power-voltage control value, a more appropriate voltage value for the usage environment can be determined with more flexibility.

Fourth Preferred Embodiment

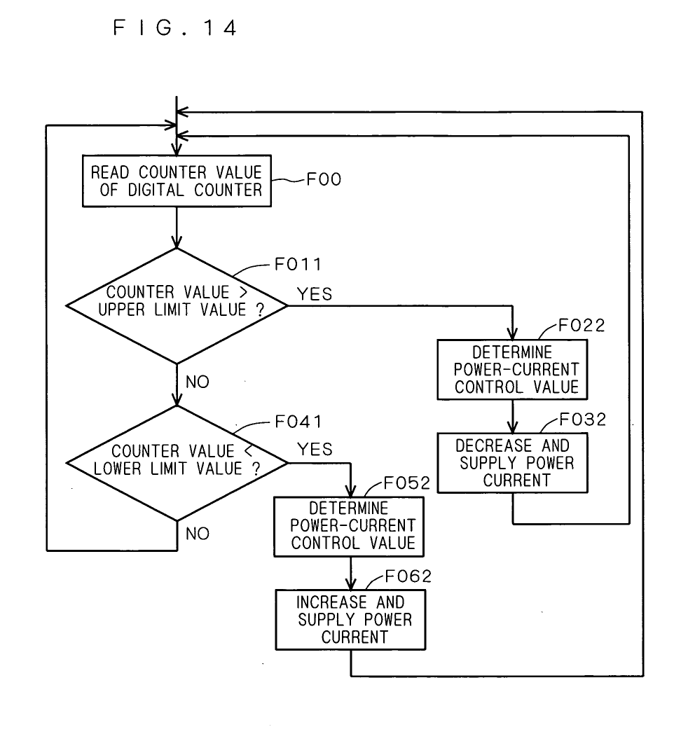

FIG. 13 is a block diagram illustrating a configuration to which a clock generation technique according to a fourth preferred embodiment of the present invention is applicable. The configuration includes two configurations of the third preferred embodiment shown in FIG. 12, both sharing the bus 6 and the use of the reference clock RCL.

More specifically, there are provided clock generation circuits 1A and 1B both receiving the reference clock RCL, a logic circuit 2A receiving a logic-circuit clock CLKA from the clock generation circuit 1A, a logic circuit 2B receiving a logic-circuit clock CLKB from the clock generation circuit 1B, a power supplier 4A supplying power to the clock generation circuit 1A and the logic circuit 2A, a power supplier 4B supplying power to the clock generation circuit 1B and the logic circuit 2B, and CPUs 7A and 7B. The clock generation circuits 1A and 1B (especially their respective multiplier circuits), the power suppliers 4A and 4B, and the CPUs 7A and 7B are interconnected by the bus 6.

The configurations of the clock generation circuits 1A and 1B are, for example, identical to that of the clock generation circuit 1 of the first preferred embodiment. The logic-circuit clocks CLKA and CLKB are generated, for example in a similar manner to the logic-circuit clock CLK of the first preferred embodiment.

From the clock generation circuits 1A and 1B, counter values KA, KB are respectively read out. The power suppliers 4A and 4B conduct the aforementioned power supply at voltage values based respectively on control information CNTA and CNTB each including the power-voltage control value.

In the aforementioned configuration, as in the third preferred embodiment, the CPU 7A can obtain the counter value KA to generate the control information CNTA, and the CPU 7B can obtain the counter value KB to generate the control information CNTB.

Further in this preferred embodiment, the CPU 7B can obtain the counter value KA to generate the control information CNTA. Thereby, even when the CPU 7A cannot afford to generate the control information CNTA due to processing overload, the power supplier 4A can supply power at an appropriate voltage.

That is, the CPU 7A can allow not only the power supplier 4A but also the power supplier 4B to supply power at an appropriate voltage. Similarly, the CPU 7B can allow not only the power supplier 4B but also the power supplier 4A to supply power at an appropriate voltage. Further, the CPU 7B can also allow both the power suppliers 4A and 4B to supply power at appropriate voltages.

Fifth Preferred Embodiment

The processing speeds of the unit delay elements increase with increasing power current, and accordingly the counter value K is incremented. On the contrary, the processing speeds of the unit delay elements decrease with decreasing power current, and accordingly the counter value K is decremented. Thus, even if voltage-value control in the techniques described in the first through fourth preferred embodiments is replaced by current-value control, a similar effect can be achieved.

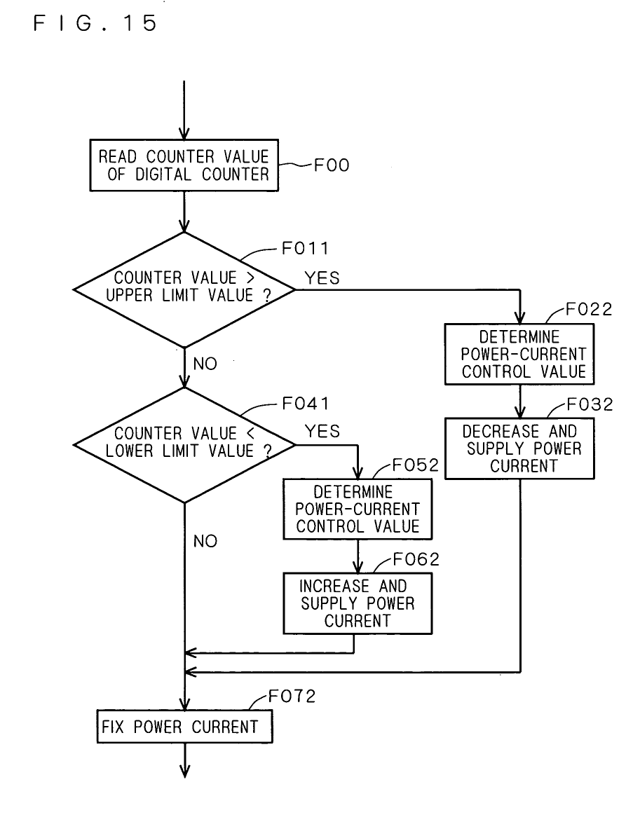

FIG. 14 is a flow chart illustrating a first operation according to a fifth preferred embodiment of the present invention, the operation being equivalent to the first preferred embodiment. That is, the flow chart is such that steps F021, F031, F051, and F061 are replaced respectively by steps F022, F032, F052, and F062.

In both steps F022 and F052, the power controller 31 determines a power-current control value which is one of parameters of operating power. In step F032, the power supplier 4 decreases the current value to supply power, whereas in step F062, the power supplier 4 increases the current value to supply power. However, it is desirable that the power-current control value be determined within the range where the digital PLL circuit 1P can be locked at a desired frequency. This is in order to generate the logic-circuit clock CLK having a stable frequency.

In this flow chart, also, the processing of step F00 is started after the digital PLL circuit 1P is locked. Further, when the process returns to step F00 from any of steps F041, F062, and F032, a predetermined time interval (e.g., a predetermined clock cycle) may be waited before the execution of step F00. This is because there is considered to be little need to change the power current within a short time.

The flow chart of FIG. 14 can be implemented by using the configuration of the first preferred embodiment shown in FIG. 1.

By the aforementioned process, in the case of a wide operating margin, it is possible, by decreasing the power current, to reduce power consumption and noise without degradation of desired performance. In the case of a small operating margin, it is possible, by increasing the power current, to prevent the occurrence of malfunctions.

In this way, the power current provided to the clock generation circuit 1 and the logic circuit 2 can be controlled to an appropriate value for variations in device manufacturing and in the usage environment. This further eliminates the need to allow for excess margin in circuit design and hence allows the design of a circuit that is fast, small, and consumes little electricity.

It is noted that, as in the first preferred embodiment, the power-current control value may not necessarily be updated regularly. For example if the power-current control value is once determined at the start of the supply of operating power to the semiconductor integrated circuit including the clock generation circuit 1 and the logic circuit 2, the power current may be fixed thereafter.

FIG. 15 is a flow chart illustrating an operation according to the above modification. In this flow chart, also, the processing of step F00 is started after the digital PLL circuit 1P is locked. As compared with the flow chart of FIG. 14, this flow chart is such that, when the result of the determination is negative in step F041, when the processing of step F032 is completed, and when the processing of step F062 is completed, the process proceeds to step F072 to fix the power current which is then supplied. The power-current control value will not be updated, and thus the power current will remain fixed, until the application of power to the aforementioned semiconductor integrated circuit is cut off.

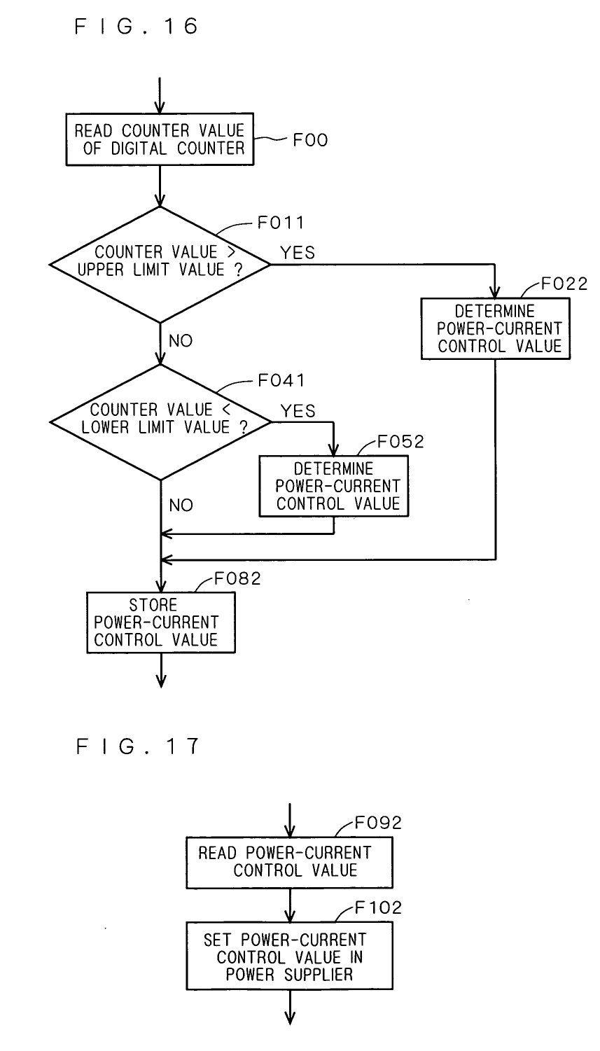

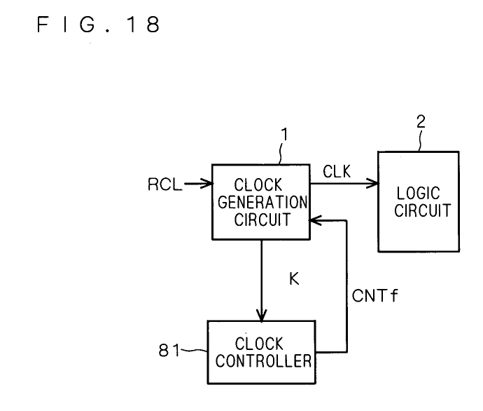

FIGS. 16 and 17 are flow charts illustrating a second operation according to this preferred embodiment, the operation being equivalent to the second preferred embodiment. More specifically, the flow charts are such that steps F021, F051, F081, F091, and F101 are replaced respectively by steps F022, F052, F082, F092, and F102. In this flow chart, also, the processing of step F00 is started after the digital PLL circuit 1P is locked.

In step F052, the power-control-information storage 5 stores the power-current control value. The power-current control value is read out of the power-control-information storage 5 in step F092 and is set in the power supplier 4 in step F102. Thereby, power supply to the clock generation circuit 1 and the logic circuit 2 can be made with an appropriate current value, on the basis of the stored power-current control value.

By adopting the flow chart of FIG. 17 into manufacturing test of the semiconductor integrated circuit including the clock generation circuit 1 and the logic circuit 2, even if there exists an individual difference depending on variations in the manufacture of semiconductor integrated circuits, a subsequent power supply can be made with an appropriate current value for individual semiconductor integrated circuits. There is also the advantage that it is easy, by using the power-current control value, to classify the products according to the performance of the semiconductor integrated circuit.

The power-control-information storage 5 can be implemented by using a non-volatile memory such as a flash memory; a laser-trimmed memory; or a recording medium (e.g., a hard disk or a flexible disk) which is accessed by a computer.

Although the power current is once fixed, it is of course desirable to use additionally the technique described in the first operation of this preferred embodiment in order to obtain an appropriate current value for the usage environment such as temperature.

The flow charts illustrated in FIGS. 16 and 17 can be implemented by using the configuration of the second preferred embodiment shown in FIG. 9.

As further alternatives, control of the power current value may be exercised by using the configuration of the third preferred embodiment shown in FIG. 12 or the configuration of the fourth preferred embodiment shown in FIG. 13. In this case, also, a similar effect to that described in the third or fourth preferred embodiment can be achieved.

Sixth Preferred Embodiment

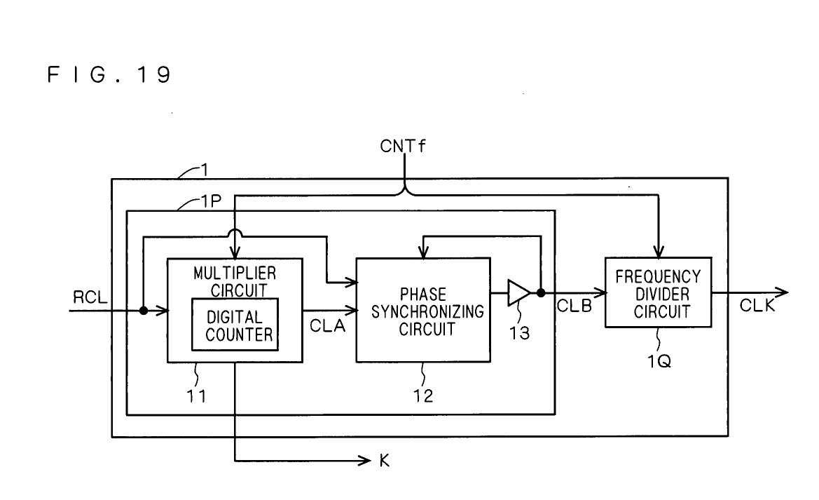

FIG. 18 is a block diagram illustrating a configuration to which a clock generation technique according to a sixth preferred embodiment of the present invention is applicable. The clock generation circuit 1 generates the logic-circuit clock CLK on the basis of the reference clock RCL and outputs the clock CLK to the logic circuit 2. The clock generation circuit 1 and the logic circuit 2 are formed, for example on the same semiconductor substrate.

The clock generation circuit 1 changes the frequency of the logic-circuit clock CLK according to a control signal CNTf obtained from a clock controller 81. The clock controller 81 may be provided within the same semiconductor integrated circuit as the clock generation circuit 1 and the logic circuit 2, or it may be provided outside the integrated circuit.

The control signal CNTf is generated by the clock controller 81 on the basis of the counter value K obtained from the clock generation circuit 1.

FIG. 19 is a block diagram illustrating a configuration of the clock generation circuit 1. The configuration of the clock generation circuit 1 according to this preferred embodiment is different from that of the first preferred embodiment (see FIG. 2), in that the control signal CNTf is capable of being fed to either or both of the multiplier circuit 11 and the frequency divider circuit 1Q. The other components are configured in the same manner as those described in the first preferred embodiment.

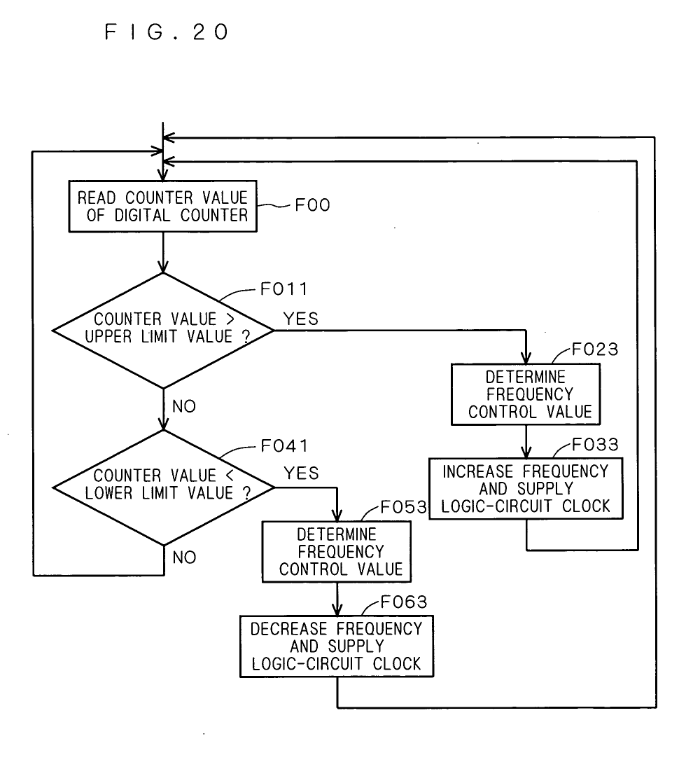

FIG. 20 is a flow chart illustrating an operation according to the sixth preferred embodiment of the present invention. The flow chart is such that steps F021, F031, F051, and F061 in the flow chart of FIG. 7, which illustrates the operation of the first preferred embodiment, are replaced respectively by steps F023, F033, F053, and F063.

In both steps F023 and F053, the clock controller 81 determines a frequency control value. The frequency control value is included in the control signal CNTf. The clock generation circuit 1 either increases the frequency in step F033 or decreases the frequency in step F063, and supplies the logic-circuit clock CLK to the logic circuit 2. Here, it is desirable that the frequency control value be determined within the range where the digital PLL circuit 1P can be locked at a desired frequency. This is in order to generate the logic-circuit clock CLK having a stable frequency.

In this flow chart, also, the processing of step F00 is started after the digital PLL circuit 1P is locked. Further, when the process returns to step F00 from any of steps F041, F063, and F033, a predetermined time interval (e.g., a predetermined clock cycle) may be waited before the execution of step F00. This is because there is considered to be little need to change the frequency within a short time.

The frequency can be increased, specifically by either or both increasing the multiplication ratio in the multiplier circuit 11 and decreasing the division ratio in the frequency divider circuit 1Q. The frequency can be decreased, specifically by either or both decreasing the multiplication ratio in the multiplier circuit 11 and increasing the division ratio in the frequency divider circuit 1Q. In this way, control of increase and decrease in frequency can be implemented by using either or both of the multiplier circuit 11 and the frequency divider circuit 1Q; and therefore, the control signal CNTf is capable of being fed to either or both of the multiplier circuit 11 and the frequency divider circuit 1Q.

When the control signal CNTf is fed to the multiplier circuit 11, the controller 115 of FIG. 3 receives the control signal CNTL In view of the N-th rising edge of the output DL-Out at which time the controller 115 will negate the control signal DL-ACT, the controller 115 is configured to change the integer N according to the control signal CNTf. When the control signal CNTf is fed to the frequency divider circuit 1Q, the frequency divider circuit 1Q is configured to change the division ratio according to the control signal CNTf.

In order to obtain, for example, the logic-circuit clock CLK having a frequency of 33 MHz from the reference clock RCL having a frequency of 25 MHz, the multiplication ratio and the division ratio should respectively be 4 and one-third. In this way, when control using the control signal CNTf is required for both the multiplier circuit 11 and the frequency divider circuit 1Q, the control signal CNTf should be composed, for example of a plurality of bits so that higher-order and lower-order bits of the control signal CNTf are used for control of the multiplication ratio and the division ratio, respectively.

As the unit delay elements have better characteristics within manufacturing variations, as the temperature is decreased and as the power voltage or current is increased, the processing speeds of the unit delay elements are increased and accordingly the counter value K is incremented. On the contrary, as the unit delay elements have poorer characteristics, as the temperature is increased and as the power voltage or current is decreased, the processing speeds of the unit delay elements are decreased and accordingly the counter value K is decremented.

From the above, in the former case of a wide operating margin, control is exercised to increase the frequency, thereby allowing the logic circuit 2 to operate with higher efficiency than required. In the latter case of a small operating margin, control is exercised to decrease the frequency, thereby preventing the occurrence of malfunctions.

The above advantage is especially remarkable in the case where a circuit, such as the logic circuit 2, which includes a great number of semiconductor devices (e.g., transistors) is formed on the same semiconductor substrate as the clock generation circuit 1. This is because, since semiconductor devices forming the clock generation circuit 1 and the logic circuit 2 are formed on the same semiconductor substrate, they are believed to show mutually similar characteristics relative to the usage environment such as temperature; and therefore, it is possible in the logic circuit 2 to reduce power consumption and noise and to prevent the occurrence of malfunctions.

Thus, according to this preferred embodiment, the frequency of the logic-circuit clock CLK which is provided from the clock generation circuit 1 to the logic circuit 2 can be increased as high as possible relative to variations in device manufacturing and in the usage environment.

It is noted that the frequency control value may not necessarily be updated regularly, as in the case of the power-voltage control value or the power-current control value. For example if the frequency control value is once determined at the start of the supply of operating power to the semiconductor integrated circuit including the clock generation circuit 1 and the logic circuit 2, the frequency may be fixed thereafter.

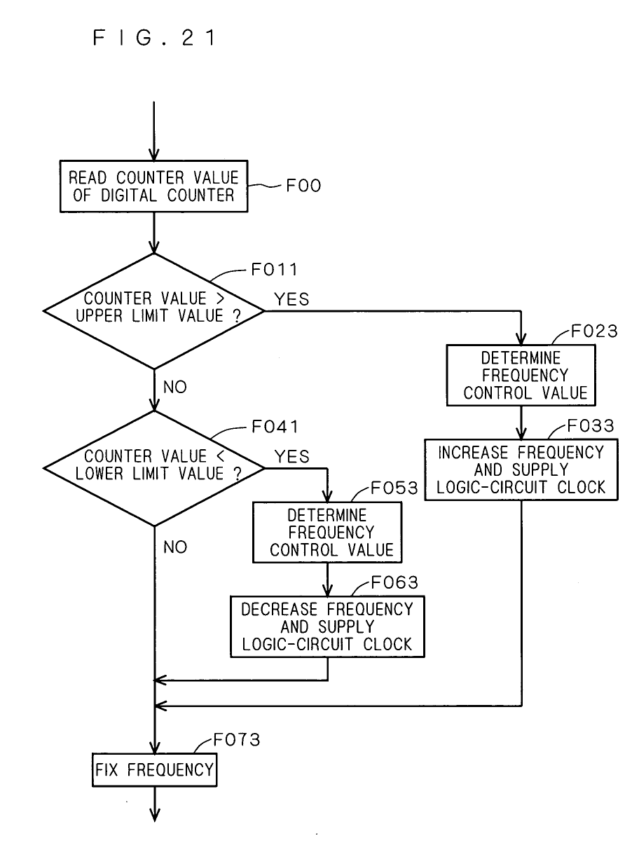

FIG. 21 is a flow chart illustrating an operation according to the above modification. The flow chart is such that modifications are made to the processing of the cases where the result of the determination is negative in step F041, where the processing of step F033 is completed, and where the processing of step F063 is completed, in the flow chart of FIG. 20. In this flow chart, also, the processing of step F00 is started after the digital PLL circuit 1P is locked.

More specifically, while in the flow chart of FIG. 20 the process in any of the aforementioned cases returns to step F00 to set a new frequency, the process in the flow chart of FIG. 21 proceeds to step F073 to fix the frequency. The frequency control value will not be updated, and thus the frequency will remain fixed, until the application of power to the aforementioned semiconductor integrated circuit is cut off.

Seventh Preferred Embodiment

FIG. 22 is a block diagram illustrating a configuration to which a clock generation technique according to a seventh preferred embodiment of the present invention is applicable. The configuration is such that a clock-control-information storage 9 is added to the configuration of the sixth preferred embodiment shown in FIG. 18. Therein, the clock generation circuit 1 generates and provides to the logic circuit 2 the logic-circuit clock CLK having a frequency which is based on the control signal CNTf obtained from the clock controller 81.

For example, the clock generation circuit 1, the logic circuit 2, the clock controller 81, and the clock-control-information storage 9 are formed within a chip. The control signal CNTf is capable of being read outside of the chip. During testing, a tester is connected to the chip to read out and store the control signal CNTf. In shipments of chips, the control signal CNTf stored in the tester is stored in the clock-control-information storage 9.

Like the power-control-information storage 5, the clock-control-information storage 9 can be implemented by using a non-volatile memory such as a flash memory; or a laser-trimmed memory.

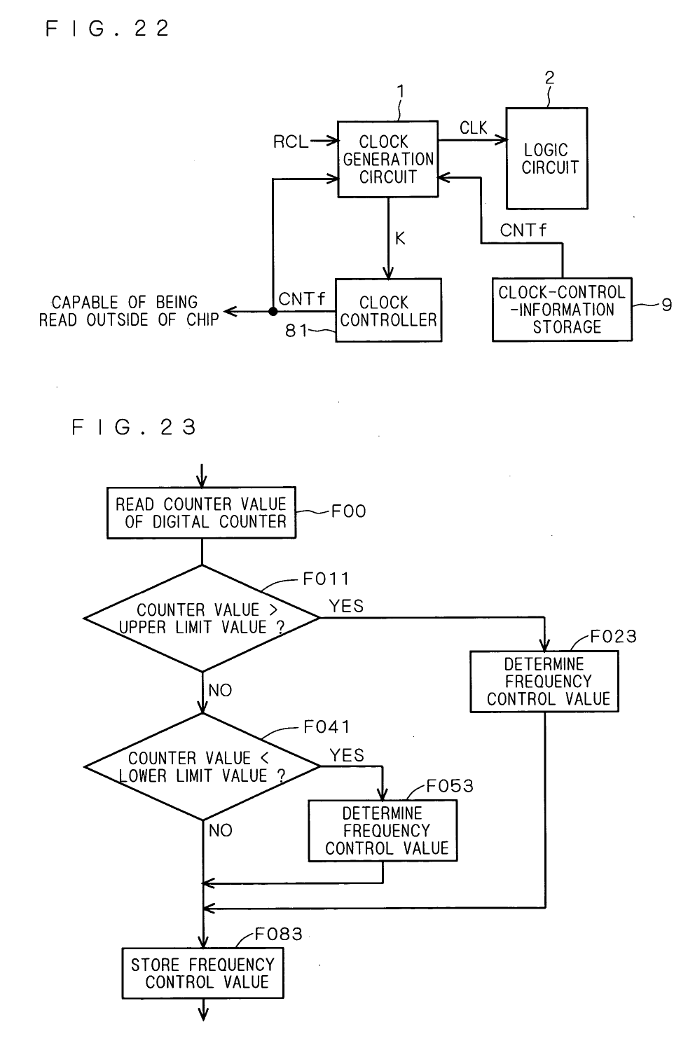

FIG. 23 is a flow chart illustrating an operation according to this preferred embodiment. As compared with the flow chart of FIG. 21, this flow chart is such that step F073 is replaced by step F083 and the processing of steps F033 and F063 is omitted. In step F083, the clock-control-information storage 9 stores the frequency control value.

FIG. 24 is a flow chart illustrating power supply using the frequency control value stored in the clock-control-information storage 9. The frequency control value is read out of the clock-control-information storage 9 in step F093 and is provided to the clock generation circuit 1 in step F103. Thereby, the clock generation circuit 1 can generate the logic-circuit clock CLK having an appropriate frequency, on the basis of the stored frequency control value.

The flow chart of FIG. 23 is applicable to, for example, manufacturing test of the semiconductor integrated circuit including the clock generation circuit 1 and the logic circuit 2. During the manufacturing test, an appropriate frequency for the clock generation circuit 1 and the logic circuit 2 is determined and stored in the clock-control-information storage 9. Thereby, even if there exists an individual difference depending on variations in the manufacture of semiconductor integrated circuits, a subsequent clock generation can be made with an appropriate frequency for individual semiconductor integrated circuits.

There is also the advantage that, because the frequency control value obtained by execution of the flow chart of FIG. 23 is stored in the clock-control-information storage 9, it is easy, by using the frequency control value, to classify the products according to the performance of the semiconductor integrated circuit.

Although the frequency is once fixed, it is of course desirable to use additionally the technique described in the sixth preferred embodiment in order to obtain an appropriate frequency for the usage environment such as temperature. For use in combination with the technique described in the sixth preferred embodiment, the configuration illustrated in FIG. 22 includes a path over which the control signal CNTf is directly given to the clock generation circuit 1.

Eighth Preferred Embodiment

In this preferred embodiment, the function performed by the clock controller 81 in the sixth preferred embodiment is performed by a CPU (central processing unit).

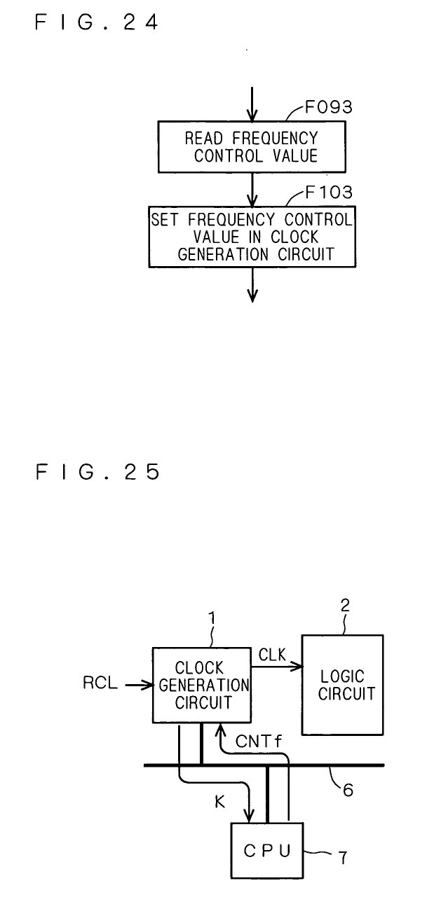

FIG. 25 is a block diagram illustrating a configuration to which a clock generation technique according to an eighth preferred embodiment of the present invention is applicable. As compared with the configuration of the sixth preferred embodiment shown in FIG. 18, this configuration is such that the clock controller 81 is replaced by the CPU 7, and the clock generation circuit 1 (especially the multiplier circuit 11 therein) is connected to the CPU 7 through the bus 6. Like the clock controller 81, the CPU 7 may be provided within the same semiconductor integrated circuit as the clock generation circuit 1 and the logic circuit 2, or it may be provided outside the integrated circuit.

Similar to the sixth preferred embodiment, this preferred embodiment also permits the operations illustrated in the flow charts of FIGS. 20 and 21. More specifically, the counter value K which is read out in step F00 is provided through the bus 6 to the CPU 7, which performs the processing of steps F023 and F053. Then, the control signal CNTf is given from the CPU 7 to the clock generation circuit 1 through the bus 6.

According to this preferred embodiment, since the CPU 7 determines the frequency control value, a more appropriate frequency for the usage environment can be determined with more flexibility.

Ninth Preferred Embodiment

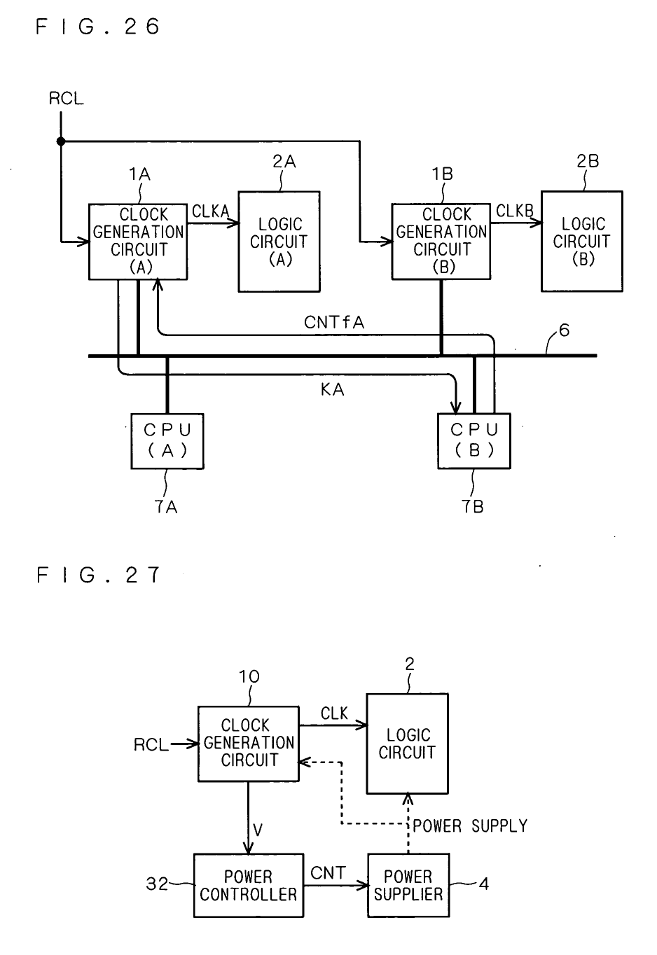

FIG. 26 is a block diagram illustrating a configuration to which a clock generation technique according to a ninth preferred embodiment of the present invention is applicable. The configuration includes two configurations of the eighth preferred embodiment shown in FIG. 25, both sharing the bus 6 and the use of the reference clock RCL.

More specifically, there are provided the clock generation circuits 1A and 1B both receiving the reference clock RCL, the logic circuit 2A receiving the logic-circuit clock CLKA from the clock generation circuit 1A, the logic circuit 2B receiving the logic-circuit clock CLKB from the clock generation circuit 1B, and the CPUs 7A and 7B. The clock generation circuits 1A, 1B (especially their respective multiplier circuits) and the CPUs 7A, 7B are interconnected by the bus 6.

The configurations of the clock generation circuits 1A and 1B are, for example, identical to that of the clock generation circuit 1 of the first preferred embodiment. The logic-circuit clocks CLKA and CLKB are generated, for example in a similar manner to the logic-circuit clock CLK of the first preferred embodiment.

From the clock generation circuits 1A and 1B, the counter values KA, KB are respectively read out. The logic-circuit clocks CLKA and CLKB are generated at frequencies based respectively on control information CNTfA and CNTfB each including the frequency control value.

In the aforementioned configuration, as in the eighth preferred embodiment, the CPU 7A can obtain the counter value KA to generate the control information CNTfA, and the CPU 7B can obtain the counter value KB to generate the control information CNTfB.

Further in this preferred embodiment, the CPU 7B can obtain the counter value KA to generate the control information CNTfA. Thereby, even when the CPU 7A cannot afford to generate the control information CNTfA due to processing overload, the clock generation circuit 1A can generate the logic-circuit clock CLKA having an appropriate frequency.

That is, the CPU 7A can not only allow the clock generation circuit 1A to generate the logic-circuit clock CLKA having an appropriate frequency, but can also allow the clock generation circuit 1B to generate the logic-circuit clock CLKB having an appropriate frequency. Similarly, the CPU 7B can not only allow the clock generation circuit 1B to generate the logic-circuit clock CLKB having an appropriate frequency, but can also allow the clock generation circuit 1A to generate the logic-circuit clock CLKA having an appropriate frequency. Further, the CPU 7B can also allow both the clock generation circuits 1A and 1B to generate respectively the logic-circuit clocks CLKA and CLKB having appropriate frequencies.

B. Application to Analog PLL

The techniques described in the first through ninth preferred embodiments are also applicable to analog PLLs.

Tenth Preferred Embodiment

FIG. 27 is a block diagram illustrating a configuration to which a clock generation technique according to a tenth preferred embodiment of the present invention is applicable. The configuration is such that the clock generation circuit 1 and the power controller 31 in the configuration shown in FIG. 1 are replaced respectively by a clock generation circuit 10 and a power controller 32.

Like the clock generation circuit 1, the clock generation circuit 10 generates the logic-circuit clock CLK based on the reference clock RCL and outputs this clock CLK to the logic circuit 2. The clock generation circuit 10 and the logic circuit 2 are formed, for example on the same semiconductor substrate and both circuits are supplied with power from the power supplier 4.

Like the power controller 31, the power controller 32 provides the control signal CNT to the power supplier 4. The power supplier 4 and the power controller 32 may be provided within the same semiconductor integrated circuit as the clock generation circuit 10 and the logic circuit 2, or they may be provided outside the integrated circuit.

The control signal CNT is generated by the power controller 32 on the basis of a VCO control voltage V obtained from the clock generation circuit 10.

FIG. 28 is a block diagram illustrating a configuration of the clock generation circuit 10. The clock generation circuit 10 includes an analog PLL circuit 10P and a frequency divider circuit 10Q.

The analog PLL circuit 10P may employ known configurations. For example, it includes a phase comparator 101, a loop filter 102, a voltage-controlled oscillator (shown as “VCO” in the figure) 103, and a frequency divider 104. The voltage-controlled oscillator 103 receives the aforementioned VCO control voltage V from the loop filter 102 to generate and provide to the frequency divider 104 and the frequency divider circuit 10Q, a clock CLC having a frequency according to the voltage V. The frequency divider 104 frequency-divides the clock CLC to generate and provide to the phase comparator 101 a frequency-divided clock. The phase comparator 101 compares a phase difference between the above frequency-divided clock and the reference clock RCL, and according to the comparison result, the loop filter 102 generates and provides to the voltage-controlled oscillator 103 the VCO control voltage V.

The frequency divider circuit 10Q frequency-divides the clock CLC by a predetermined division ratio to generate and output the logic-circuit clock CLK.

Even for generation of the clock CLC having the same frequency, the VCO control voltage V varies according to the characteristics of devices forming the voltage-controlled oscillator 103. These device characteristics vary, for example according to manufacturing variations and usage conditions such as temperature and power voltage. That is, even if the frequency of the clock CLC is the same, the VCO control voltage V at which the analog PLL circuit 10P is in a stable condition varies according to the above manufacturing variations and usage conditions.

As the above devices have better characteristics within manufacturing variations, as the temperature is decreased and as the power voltage is increased, the VCO control voltage V is decreased. On the contrary, as the above devices have poorer characteristics, as the temperature is increased and as the power voltage is decreased, the VCO control voltage V is increased.

From the above, in the former case, control is exercised to increase the power voltage, thereby preventing the occurrence of malfunctions. In the latter case, control is exercised to decrease the power voltage, thereby allowing reductions in power consumption and noise without degradation of desired performance.

The above advantage is especially remarkable in the case where, similar to the digital PLL circuit 1P, the logic circuit 2 is formed on the same semiconductor substrate as the clock generation circuit 10.

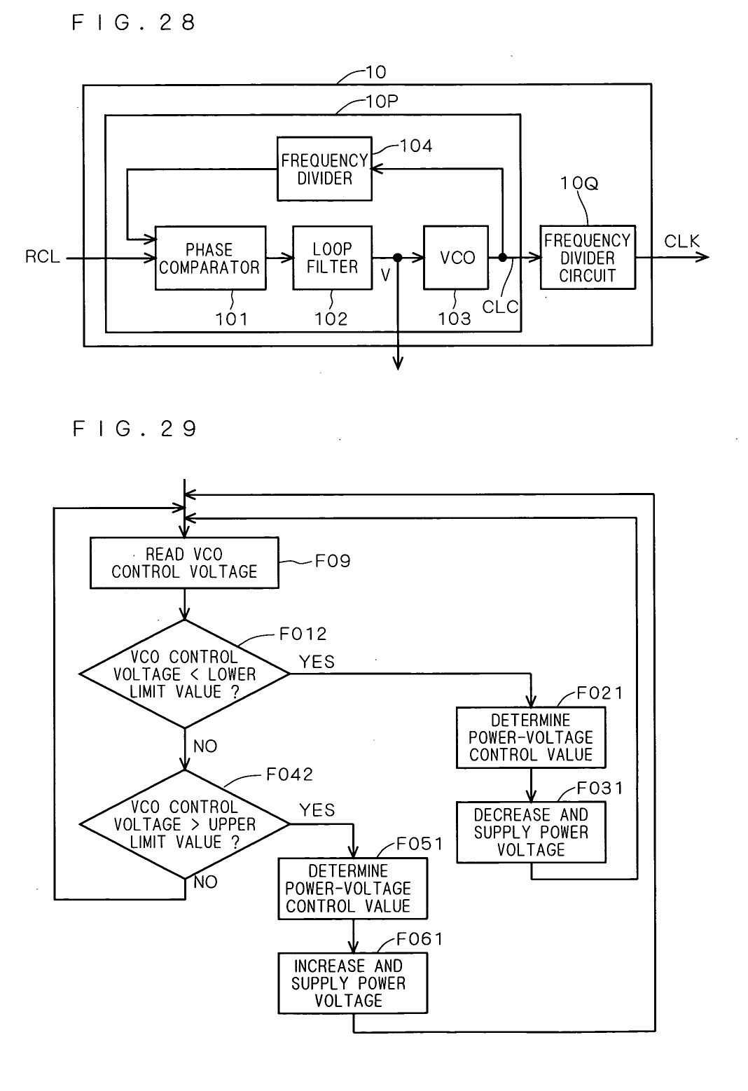

FIG. 29 is a flow chart illustrating a first operation according to the tenth preferred embodiment of the present invention, the operation being performed with the analog PLL circuit 10P being in a locked condition. Whether the analog PLL circuit 10P is locked can be detected by using well-known techniques; for example, lock detection can be performed based on the output of the phase comparator 101. The flow chart is such that steps F00, F011, and F041 in the flow chart of the first preferred embodiment shown in FIG. 7 are replaced respectively by steps F09, F012, and F042. Step F09 is performed after the analog PLL circuit 10P is locked.

In step F09, the VCO control voltage V is read out to the power controller 32 (see FIG. 27). The process then proceeds to step F012, where the power controller 32 determines whether or not the VCO control voltage V is lower than a lower limit value. If the result of the determination is positive, that is, if the VCO control voltage V is lower than the lower limit value, the process goes through the processing of steps F021 and F031 and returns to step F09. If the result of the determination is negative, that is, if the VCO control voltage V is equal to or greater than the lower limit value, the process proceeds to step F042 without going through the processing of steps F021 and F031.

In step F042, the power controller 32 determines whether or not the VCO control voltage V is greater than an upper limit value. If the result of the determination is positive, that is, if the VCO control voltage V is greater than the upper limit value, the process goes through the processing of steps F051 and F061 and returns to step F09. If the result of the determination is negative, that is, if the VCO control voltage V is equal to or lower than the upper limit value, the process returns to step F09 without going through the processing of steps F051 and F061.

From the above description, it is found that the process is divided into three branches of processing according to the magnitude of the VCO control voltage V. The first branch applies to the case where the VCO control voltage V is not less than the lower limit value and is not more than the upper limit value, in which case the power controller 32 does not perform processing that depends on the magnitude of the VCO control voltage V. The second branch applies to the case where the VCO control voltage V is lower than the lower limit value, in which case the process of decreasing the power voltage is performed. The third branch applies to the case where the VCO control voltage V is greater than the upper limit value, in which case the process of increasing the power voltage is performed.

In steps F021 and F051, it is desirable that the power-voltage control value be determined within the range where the analog PLL circuit 10P can be locked at a desired frequency. This is in order to generate the logic-circuit clock CLK having a stable frequency.

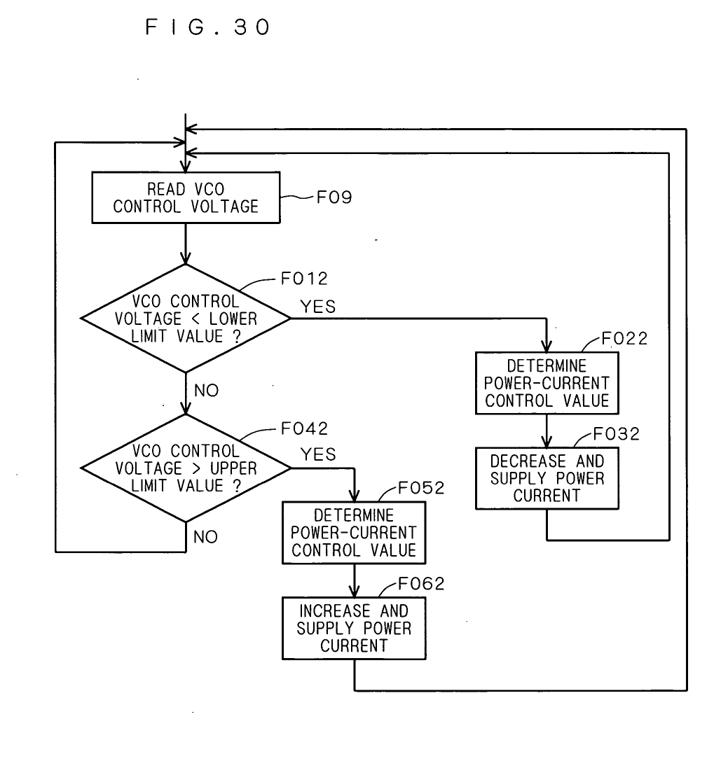

FIG. 30 is a flow chart illustrating a second operation according to the tenth preferred embodiment of the present invention. The flow chart is such that steps F00, F011, and F041 in the flow chart of the fifth preferred embodiment shown in FIG. 14 are replaced respectively by steps F09, F012, and F042. Thus, as in the first operation of the tenth preferred embodiment, a current control value based on the VCO control voltage V is employed.

In the flow chart of FIG. 29, when the process returns to step F09 from any of steps F042, F061, and F031, a predetermined time interval (e.g., a predetermined clock cycle) may be waited before the execution of step F09. This is because there is considered to be little need to change the power voltage within a short time.

Similarly, in the flow chart of FIG. 30, when the process returns to step F09 from any of steps F042, F062, and F032, a predetermined time interval (e.g., a predetermined clock cycle) may be waited before the execution of step F09. This is because there is considered to be little need to change the power current within a short time.

By the aforementioned process, as in the first and fifth preferred embodiments, it is possible to reduce power consumption and noise or to prevent the occurrence of malfunctions. The power voltage or current to be provided can be controlled to an appropriate value for variations in device manufacturing and in the usage environment. This further eliminates the need to allow for excess margin in circuit design and hence allows the design of a circuit that is fast, small, and consumes little electricity.

It is noted that the power-voltage or power-current control value may not necessarily be updated regularly. For example if the power-voltage or power-current control value is once determined at the start of the supply of operating power to the semiconductor integrated circuit including the clock generation circuit 10 and the logic circuit 2, the power voltage or current may be fixed thereafter.

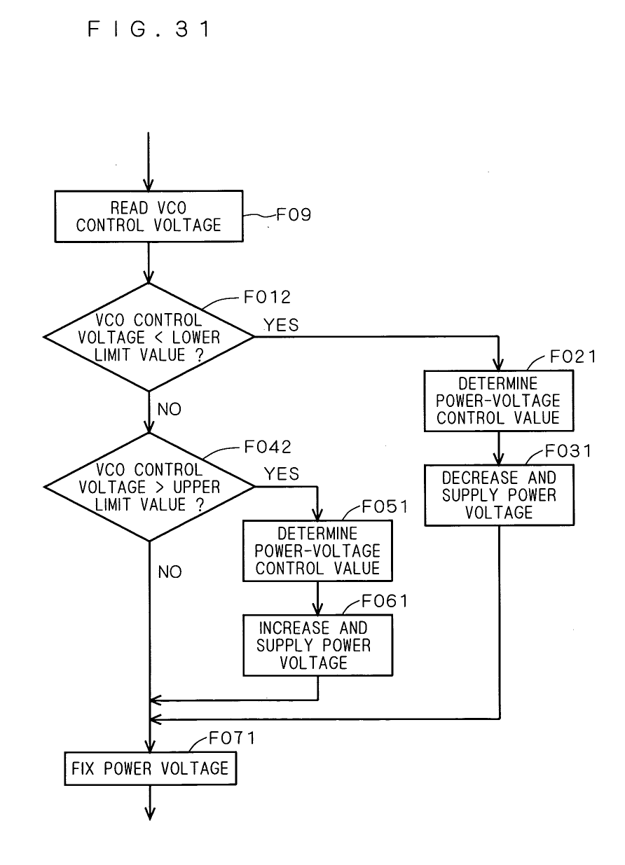

FIG. 31 is a flow chart illustrating a third operation according to the tenth preferred embodiment. The flow chart is such that steps F00, F011, and F041 in the flow chart of the first preferred embodiment shown in FIG. 8 are replaced respectively by steps F09, F12, and F042.

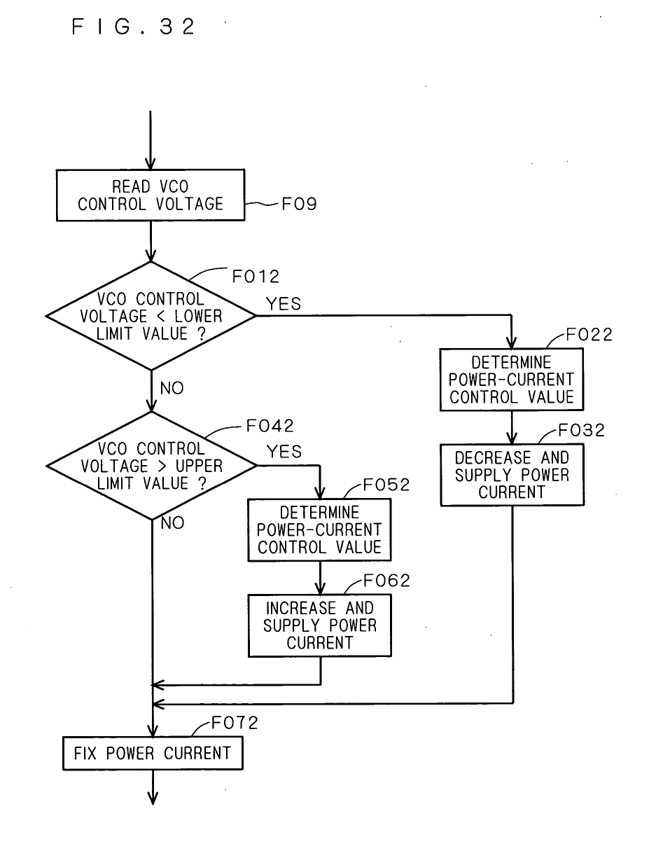

FIG. 32 is a flow chart illustrating a fourth operation according to the tenth preferred embodiment. The flow chart is such that steps F00, F011, and F041 in the flow chart of the fifth preferred embodiment shown in FIG. 15 are replaced respectively by steps F09, F12, and F042.

In either of the flow charts of FIGS. 31 and 32, step F09 is performed after the analog PLL circuit 10P is locked.

Thus, as described in the first and fifth preferred embodiments, the power-voltage or power-current control value will not be updated, and thus the power voltage or current will remain fixed, until the application of power to the aforementioned semiconductor integrated circuit is cut off.

Eleventh Preferred Embodiment

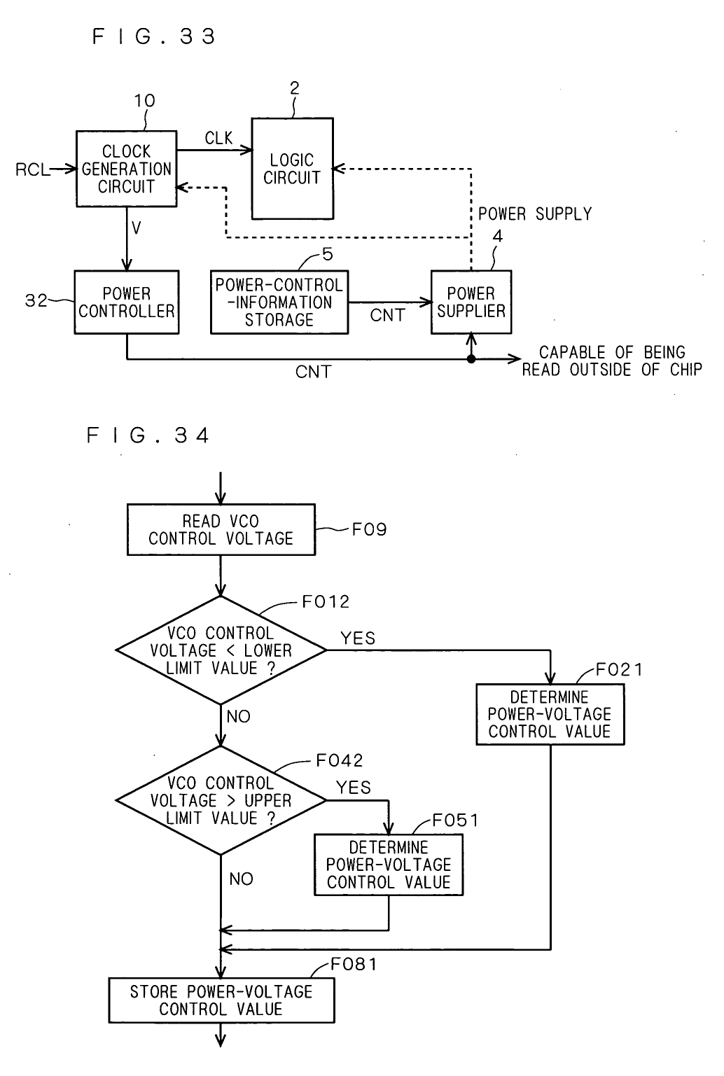

FIG. 33 is a block diagram illustrating a configuration to which a clock generation technique according to an eleventh preferred embodiment of the present invention is applicable. The configuration is such that the power-control-information storage 5 is added to the configuration of the tenth preferred embodiment shown in FIG. 27. Therein, the power supplier 4 supplies power at a voltage or current value based on the control signal CNT obtained from the power controller 32, to the clock generation circuit 10 and the logic circuit 2.

For example, the clock generation circuit 10, the logic circuit 2, the power controller 32, the power supplier 4, and the power-control-information storage 5 are formed within a chip. The control signal CNT is capable of being read outside of the chip. During testing, a tester is connected to the chip to read out and store the control signal CNT. In shipments of chips, the control signal CNT stored in the tester is stored in the power-control-information storage 5.

FIG. 34 is a flow chart illustrating a first operation according to this preferred embodiment. Step F09 is performed after the analog PLL circuit 10P is locked. The flow chart is such that steps F00, F011, and F041 in the flow chart of the second preferred embodiment shown in FIG. 10 are replaced respectively by steps F09, F012, and F042. Following this, the flow chart of the second preferred embodiment shown in FIG. 11 can be executed.

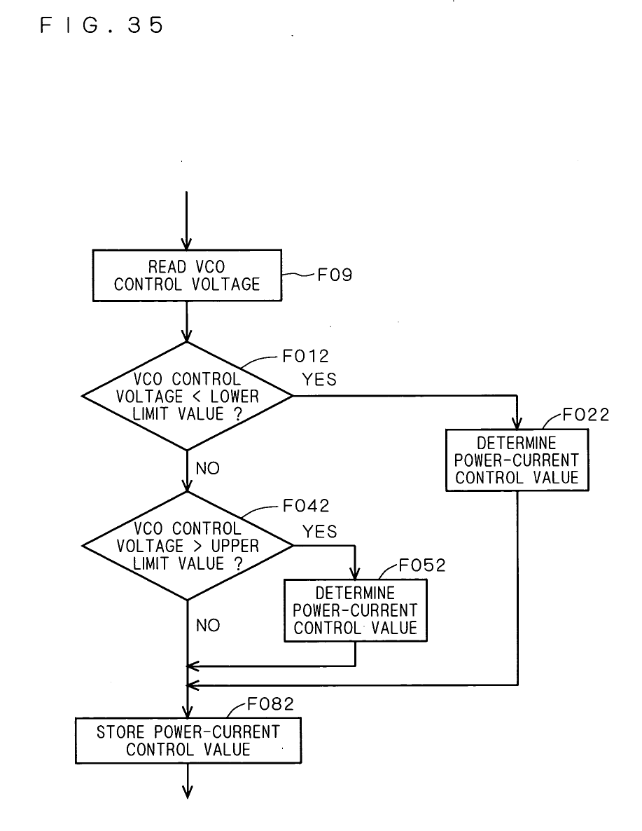

FIG. 35 is a flow chart illustrating a second operation according to this preferred embodiment. Step F09 is performed after the analog PLL circuit 10P is locked. The flow chart is such that steps F00, F011, and F041 in the flow chart of the fifth preferred embodiment shown in FIG. 16 are replaced respectively by steps F09, F012, and F042. Following this, the flow chart of the fifth preferred embodiment shown in FIG. 17 can be executed.

Also in the eleventh preferred embodiment, as in the second and fifth preferred embodiments, an appropriate power parameter, such as the power voltage or current, for the semiconductor integrated circuit is determined and stored in the power-control-information storage 5 during manufacturing test. Thereby, even if there exists an individual difference depending on variations in the manufacture of semiconductor integrated circuits, a subsequent power supply can be made with an appropriate power parameter for individual semiconductor integrated circuits. Also, it becomes easy to classify the products according to the performance of the semiconductor integrated circuit.

Twelfth Preferred Embodiment

In this preferred embodiment, the function performed by the power controller 32 in the tenth and eleventh preferred embodiments is performed by a CPU (central processing unit).

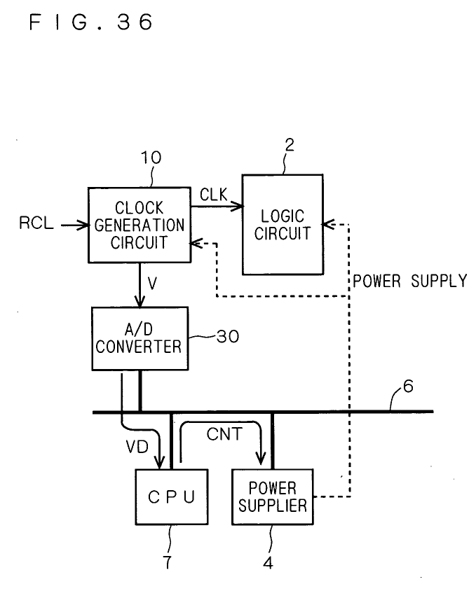

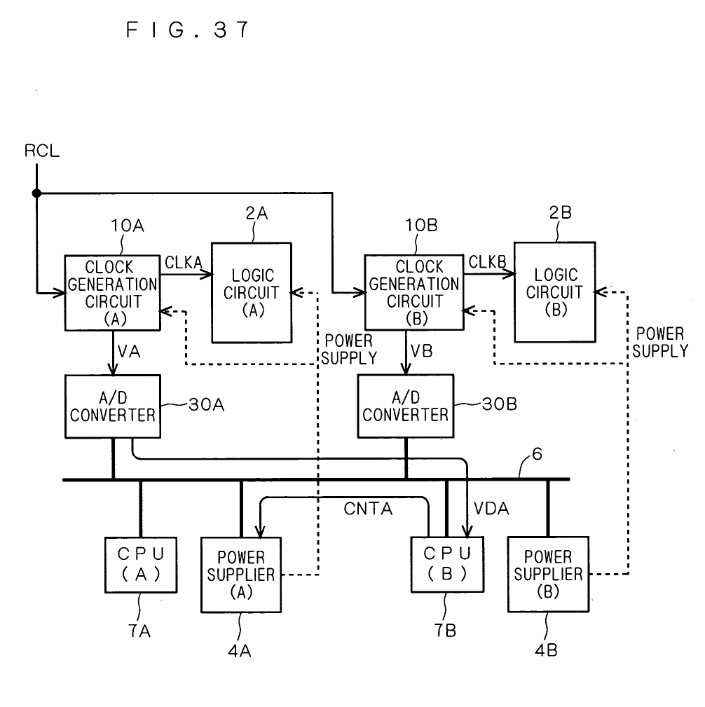

FIG. 36 is a block diagram illustrating a configuration to which a clock generation technique according to a twelfth preferred embodiment of the present invention is applicable. As compared with the configuration of the third preferred embodiment shown in FIG. 12, this configuration is such that the clock generation circuit 1 is replaced by the clock generation circuit 10 and an analog-to-digital (A-D) converter 30 is provided between the bus 6 and the clock generation circuit 10.

The A-D converter 30 converts the VCO control voltage V into a digital value VD and provides the value VD to the bus 6. In this preferred embodiment, the clock generation circuit 10 is not necessarily connected directly to the bus 6.

Like the CPU 7 and the power supplier 4, the A-D converter 30 may be provided within the same semiconductor integrated circuit as the clock generation circuit 10 and the logic circuit 2, or it may be provided outside the integrated circuit.

Similar to the tenth and eleventh preferred embodiments, this preferred embodiment also permits the operations illustrated in the flow charts of FIGS. 29 through 32. More specifically, the VCO control voltage V which is read out in step F09 is provided as the digital value VD through the bus 6 to the CPU 7, which performs the processing of step F021 or F022 and the processing of step F051 or F052. Then, the control signal CNT is given from the CPU 7 to the power supplier 4 through the bus 6.

According to this preferred embodiment, since the CPU 7 determines the power-voltage or power-current control value, a more appropriate voltage or current value for the usage environment can be determined with more flexibility.

Thirteenth Preferred Embodiment

FIG. 37 is a block diagram illustrating a configuration to which a clock generation technique according to a thirteenth preferred embodiment of the present invention is applicable. The configuration includes two configurations of the twelfth preferred embodiment shown in FIG. 36, both sharing the bus 6 and the use of the reference clock RCL.

More specifically, there are provided clock generation circuits 10A and 10B both receiving the reference clock RCL, the logic circuit 2A receiving the logic-circuit clock CLKA from the clock generation circuit 10A, the logic circuit 2B receiving the logic-circuit clock CLKB from the clock generation circuit 10B, the power supplier 4A supplying power to the clock generation circuit 10A and the logic circuit 2A, the power supplier 4B supplying power to the clock generation circuit 10B and the logic circuit 2B, the CPUs 7A and 7B, and A-D converters 30A and 30B. The A-D converters 30A and 30B, the power suppliers 4A and 4B, and the CPUs 7A and 7B are interconnected by the bus 6.

The configurations of the clock generation circuits 10A and 10B are, for example, identical to that of the clock generation circuit 10 of the tenth preferred embodiment. The logic-circuit clocks CLKA and CLKB are generated, for example in a similar manner to the logic-circuit clock CLK of the first preferred embodiment.

From the clock generation circuits 10A and 10B, VCO control voltages VA and VB are respectively read out. The VCO control voltages VA and VB are then converted respectively into digital values VDA and VDB by the A-D converters 30A and 30B, respectively. The power suppliers 4A and 4B conduct the aforementioned power supply at voltage or current values based respectively on the control information CNTA and CNTB.

In the aforementioned configuration, as in the twelfth preferred embodiment, the CPU 7A can obtain the digital value VDA to generate the control information CNTA, and the CPU 7B can obtain the digital value VDB to generate the control information CNTB.

Further in this preferred embodiment, the CPU 7B can obtain the digital value VDA to generate the control information CNTA. Thereby, even when the CPU 7A cannot afford to generate the control information CNTA due to processing overload, the power supplier 4A can supply power at an appropriate voltage or current.

That is, the CPU 7A can allow not only the power supplier 4A but also the power supplier 4B to supply power at an appropriate voltage or current. Similarly, the CPU 7B can allow not only the power supplier 4B but also the power supplier 4A to supply power at an appropriate voltage or current. Further, the CPU 7B can also allow both the power suppliers 4A and 4B to supply power at appropriate voltages or currents.

Fourteenth Preferred Embodiment

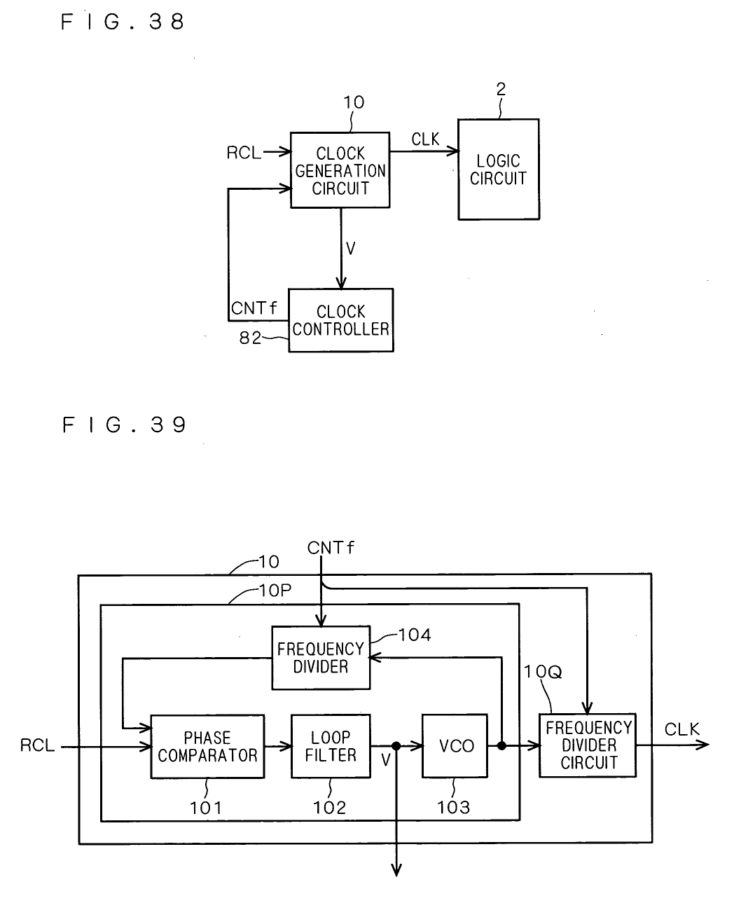

FIG. 38 is a block diagram illustrating a configuration to which a clock generation technique according to a fourteenth preferred embodiment of the present invention is applicable. The configuration is such that the clock generation circuit 1 and the clock controller 81 in the configuration of the sixth preferred embodiment shown in FIG. 18 are replaced respectively by the clock generation circuit 10 and a clock controller 82.

The clock generation circuit 10 changes the frequency of the logic-circuit clock CLK according to the control signal CNTf obtained from the clock controller 82. The clock controller 82 may be provided within the same semiconductor integrated circuit as the clock generation circuit 10 and the logic circuit 2, or it may be provided outside the integrated circuit.

The control signal CNTf is generated by the clock controller 82 on the basis of the VCO control voltage V obtained from the clock generation circuit 10.

FIG. 39 is a block diagram illustrating a configuration of the clock generation circuit 10. The configuration of the clock generation circuit 10 according to this preferred embodiment is different from that of the tenth preferred embodiment (see FIG. 28), in that the control signal CNTf is capable of being fed to either or both of the frequency divider 104 and the frequency divider circuit 10Q. The other components are configured in the same manner as those described in the tenth preferred embodiment.

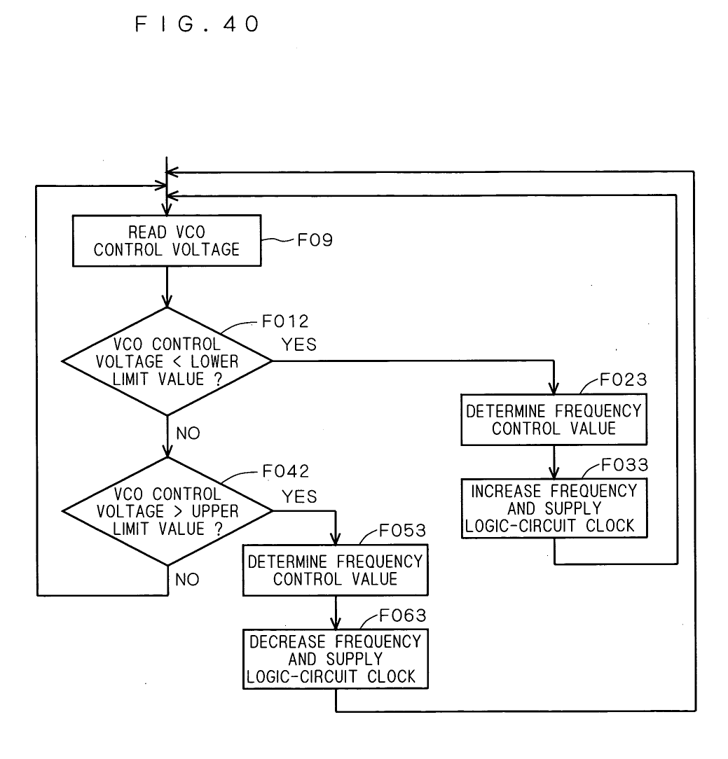

FIG. 40 is a flow chart illustrating an operation according to this preferred embodiment. The flow chart is such that steps F00, F011, and F041 in the flow chart of the sixth preferred embodiment shown in FIG. 20 are replaced respectively by steps F09, F012, and F042. Step F09 is performed after the analog PLL circuit 10P is locked. When the process returns to step F09 from any of steps F042, F063, and F033, a predetermined time interval (e.g., a predetermined clock cycle) may be waited before the execution of step F09. This is because there is considered to be little need to change the frequency within a short time.

The frequency can be increased, specifically by either or both increasing the division ratio in the frequency divider 104 and decreasing the division ratio in the frequency divider circuit 10Q. The frequency can be decreased, specifically by either or both decreasing the division ratio in the frequency divider 104 and increasing the division ratio in the frequency divider circuit 10Q. In this way, control of increase and decrease in frequency can be implemented by using either or both of the frequency divider 104 and the frequency divider circuit 10Q; and therefore, the control signal CNTf is capable of being fed to either or both of the frequency divider 104 and the frequency divider circuit 10Q. Either or both of the frequency divider 104 and the frequency divider circuit 10Q which input the control signal CNTf are configured to change the division ratio thereof according to the control signal CNTf.

Thus, as in the sixth preferred embodiment, in the case of a wide operating margin, control is exercised to increase the frequency, thereby allowing the logic circuit 2 to operate with higher efficiency than required. In the case of a small operating margin, control is exercised to decrease the frequency, thereby preventing the occurrence of malfunctions.

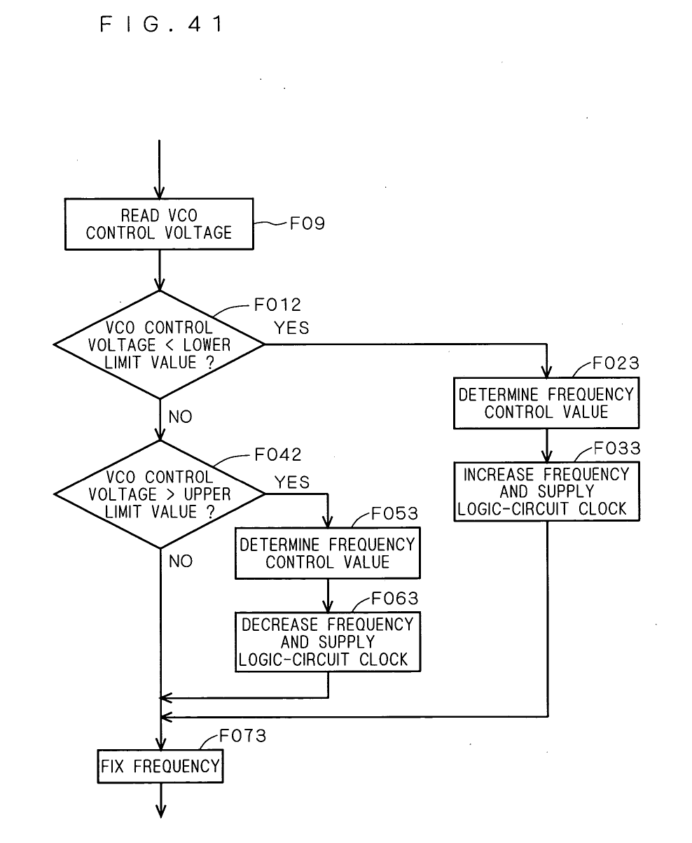

FIG. 41 is a flow chart illustrating an operation according to a modification of the fourteenth preferred embodiment. The flow chart is such that steps F00, F011, and F041 in the flow chart of the modification of the sixth preferred embodiment shown in FIG. 21 are replaced respectively by steps F09, F012, and F042. Step F09 is performed after the analog PLL circuit 10P is locked.

Thus, as in the modification of the sixth preferred embodiment, for example if the frequency control value is once determined at the start of the supply of operating power to the semiconductor integrated circuit including the clock generation circuit 10 and the logic circuit 2, the frequency may be fixed thereafter. Then, the frequency control value will not be updated, and thus the frequency will remain fixed, until the application of power to the aforementioned semiconductor integrated circuit is cut off.

Fifteenth Preferred Embodiment

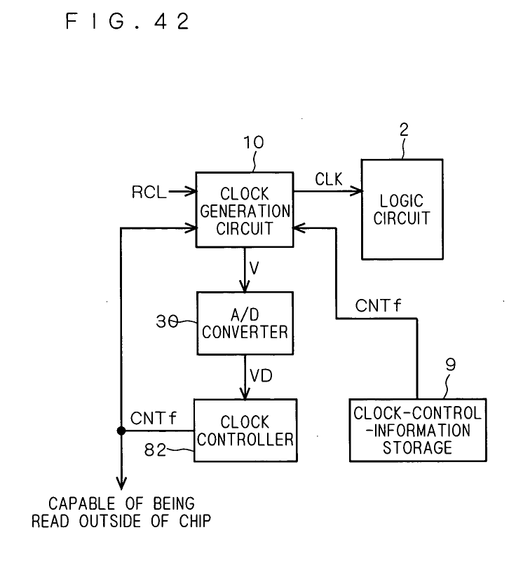

FIG. 42 is a block diagram illustrating a configuration to which a clock generation technique according to a fifteenth preferred embodiment of the present invention is applicable. The configuration is such that the clock-control-information storage 9 and the A-D converter 30 are added to the configuration of the fourteenth preferred embodiment shown in FIG. 38.

As in the seventh preferred embodiment, the clock generation circuit 10 generates and provides to the logic circuit 2 the logic-circuit clock CLK having a frequency which is based on the control signal CNTf obtained from the clock-control-information storage 9.

For example, the clock generation circuit 1, the logic circuit 2, the A-D converter 30, the clock controller 82, and the clock-control-information storage 9 are formed within a chip. The control signal CNTf is capable of being read outside of the chip. During testing, a tester is connected to the chip to read out and store the control signal CNTf. In shipments of chips, the control signal CNTf stored in the tester is stored in the clock-control-information storage 9.

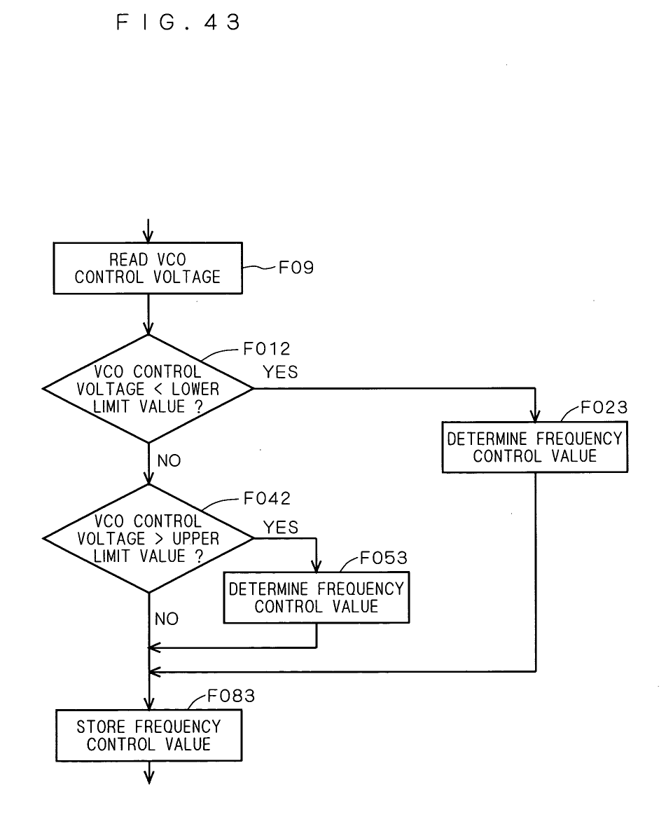

FIG. 43 is a flow chart illustrating an operation according to this preferred embodiment. The flow chart is such that steps F00, F011, and F041 in the flow chart of FIG. 23 are replaced respectively by steps F09, F012, and F042. Step F09 is performed after the analog PLL circuit 10P is locked.

Thus, as in the seventh preferred embodiment, even if there exists an individual difference depending on variations in the manufacture of semiconductor integrated circuits, a subsequent clock generation can be made with an appropriate frequency for individual semiconductor integrated circuits. Also, it becomes easy to classify the products according to the performance of the semiconductor integrated circuit.

Although the frequency is once fixed, it is of course desirable to use additionally the technique described in the fourteenth preferred embodiment in order to obtain an appropriate frequency for the usage environment such as temperature. Thus, the configuration illustrated in FIG. 42 includes a path over which the control signal CNTf is directly given to the clock generation circuit 10.

Sixteenth Preferred Embodiment

As in the twelfth preferred embodiment, the function performed by the clock controller 82 in the fourteenth and fifteenth preferred embodiments can be performed by a CPU (central processing unit).

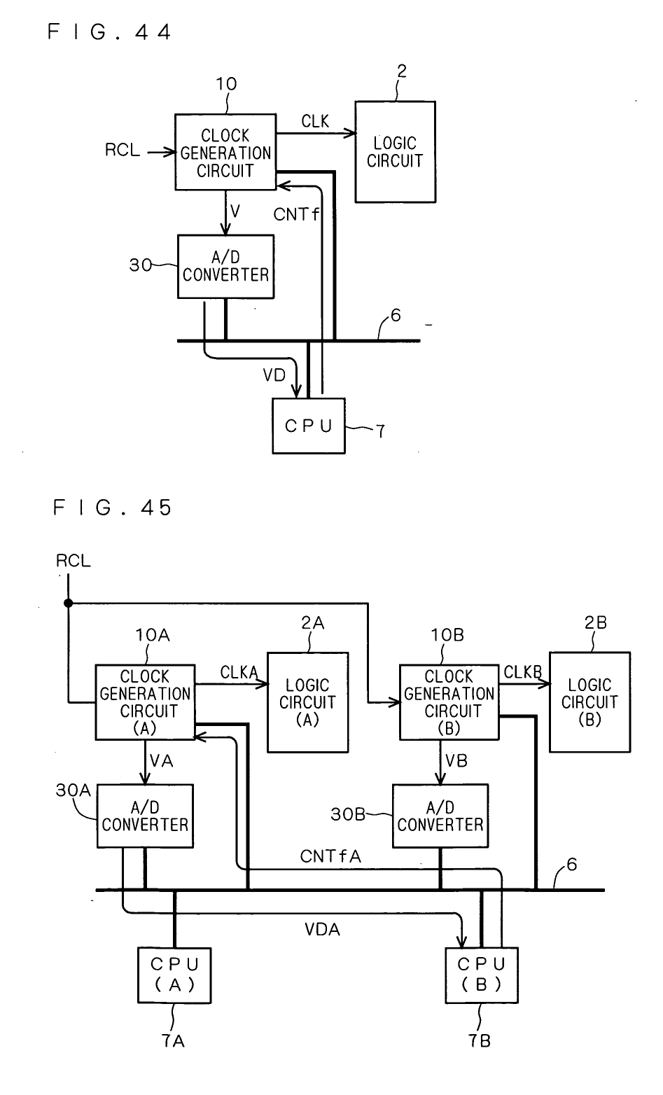

FIG. 44 is a block diagram illustrating a configuration to which a clock generation technique according to a sixteenth preferred embodiment of the present invention is applicable. As compared with the configuration of the eighth preferred embodiment shown in FIG. 25, this configuration is such that the clock generation circuit 1 is replaced by the clock generation circuit 10 and the A-D converter 30 is provided between the bus 6 and the clock generation circuit 10.

The A-D converter 30 converts the VCO control voltage V into the digital value VD and provides the value VD to the bus 6. In this preferred embodiment, the clock generation circuit 10 is also connected to the bus 6.

Similar to the fourteenth preferred embodiment, this preferred embodiment also permits the operations illustrated in the flow charts of FIGS. 40 and 41. More specifically, the VCO control voltage V which is read out in step F09 is provided as the digital value VD through the bus 6 to the CPU 7, which performs the processing of steps F023 and F053. Then, the control signal CNTf is given from the CPU 7 to the clock generation circuit 10 through the bus 6.

According to this preferred embodiment, as in the eighth preferred embodiment, since the CPU 7 determines the frequency control value, a more appropriate frequency for the usage environment can be determined with more flexibility.

Seventeenth Preferred Embodiment

FIG. 45 is a block diagram illustrating a configuration to which a clock generation technique according to a seventeenth preferred embodiment of the present invention is applicable. The configuration includes two configurations of the sixteenth preferred embodiment shown in FIG. 44, both sharing the bus 6 and the use of the reference clock RCL.

More specifically, there are provided the clock generation circuits 10A and 10B both receiving the reference clock RCL, the logic circuit 2A receiving the logic-circuit clock CLKA from the clock generation circuit 10A, the logic circuit 2B receiving the logic-circuit clock CLKB from the clock generation circuit 10B, the CPUs 7A and 7B, and the A-D converters 30A and 30B. The clock generation circuits 10A and 10B, the A-D converters 30A and 30B, and the CPUs 7A and 7B are interconnected by the bus 6.

The configurations of the clock generation circuits 10A and 10B are, for example, identical to that of the clock generation circuit 10 of the tenth preferred embodiment. The logic-circuit clocks CLKA and CLKB are generated, for example in a similar manner to the logic-circuit clock CLK of the first preferred embodiment.

From the clock generation circuits 10A and 10B, the VCO control voltages VA and VB are respectively read out. The VCO control voltages VA and VB are then converted respectively into the digital values VDA and VDB by the A-D converters 30A and 30B, respectively. The clock generation circuits 10A and 10B generate respectively the logic-circuit clocks CLKA and CLKB having frequencies based respectively on the control information CNTFA and CNTFB.

Thus, as in the ninth preferred embodiment, even when the CPU 7A cannot afford to generate the control information CNTA due to processing overload, the clock generation circuits 10A and 10B can generate respectively the logic-circuit clocks CLKA and CLKB having appropriate frequencies. Further, the CPU 7A can allow not only the clock generation circuit 10A to generate the logic-circuit clock CLKA having an appropriate frequency, but can also allow the clock generation circuit 10B to generate the logic-circuit clock CLKB having an appropriate frequency. Similarly, the CPU 7B can allow not only the clock generation circuit 10B to generate the logic-circuit clock CLKB having an appropriate frequency, but can also allow the clock generation circuit 10A to generate the logic-circuit clock CLKA having an appropriate frequency. Furthermore, the CPU 7B can also allow both the clock generation circuits 10A and 10B to generate respectively the logic-circuit clocks CLKA and CLKB having appropriate frequencies.

In the clock generation systems according to the first through fifth and tenth through thirteenth preferred embodiments, the logic circuit 2 is to receive the logic-circuit clock CLK. It is therefore understood that the logic circuit 2 is not an absolutely necessary constituent in the clock generation system according to the present invention. As one example, the clock generation system and the logic circuit 2 may be configured as a semiconductor integrated circuit. In such a semiconductor integrated circuit, power is supplied from the power supplier 4 in the clock generation system, and the logic circuit 2 operates in synchronization with the logic-circuit clock CLK obtained from the clock generation circuit 1 or 10. This will decrease an operating power voltage or current of the logic circuit, thereby resulting in low power consumption of the logic circuit that consumes much power in the semiconductor integrated circuit.

While the invention has been shown and described in detail, the foregoing description is in all aspects illustrative and not restrictive. It is therefore understood that numerous modifications and variations can be devised without departing from the scope of the invention.

1. A clock generation system comprising:
a multiplier circuit including a ring oscillator and a control circuit,
said ring oscillator including a delay element and a logic gate, and outputting an output clock signal from said logic gate, a delay amount of said delay element being controlled based on a digital value, said logic gate performing a logical operation upon an output of said delay element,
said control circuit controlling an operation of said logic gate and said digital value on the basis of a phase difference between the output of said delay element and a reference clock signal; and
a power supplier for supplying operating power to said multiplier circuit,
wherein a parameter of said operating power is controlled based on said digital value.

2. The clock generation system according to claim 1, wherein
a voltage of said operating power is employed as a parameter of said operating power,
said power supplier decreases said voltage of said operating power when said digital value exceeds a predetermined upper limit value, and
said power supplier increases said voltage of said operating power when said digital value is lower than a predetermined lower limit value.

3. The clock generation system according to claim 1, wherein
a current of said operating power is employed as a parameter of said operating power,
said power supplier decreases said current of said operating power when said digital value exceeds a predetermined upper limit value, and
said power supplier increases said current of said operating power when said digital value is lower than a predetermined lower limit value.

4. The clock generation system according to claim 1, further comprising:
a storage for storing said parameter.

5. The clock generation system according to claim 1, further comprising:
a CPU for controlling a parameter of said operating power on the basis of said digital value.

6. The clock generation system according to claim 5, wherein
said multiplier circuit, said power supplier and said CPU respectively include a plurality of multiplier circuits, a plurality of power suppliers and a plurality of CPUs,
said clock generation system further comprising:
a bus for interconnecting said plurality of CPUs, said plurality of multiplier circuits and said plurality of power suppliers.

7. A clock generation system comprising:
a ring oscillator including a delay element and a logic gate, and outputting an output clock signal from said logic gate, a delay amount of said delay element being controlled based on a digital value, said logic gate performing a logical operation upon an output of said delay element; and
a control circuit for controlling an operation of said logic gate and said digital value on the basis of a phase difference between the output of said delay element and a reference clock signal,
wherein a frequency of said output clock signal is controlled based on said digital value.

8. The clock generation system according to claim 7, further comprising:
a storage for storing the frequency of said output clock signal which is controlled based on said digital value.

9. The clock generation system according to claim 7, further comprising:
a CPU for controlling the frequency of said output clock signal on the basis of said digital value.

10. The clock generation system according to claim 9, wherein
said multiplier circuit and said CPU respectively include a plurality of multiplier circuits and a plurality of CPUs,
said clock generation system further comprising:
a bus for interconnecting said plurality of CPUs and said plurality of multiplier circuits.

11. A clock generation system comprising:
a multiplier circuit including a ring oscillator and a control circuit,
said ring oscillator including a delay element and a logic gate, and outputting an output clock signal from said logic gate, a delay amount of said delay element being controlled based on a digital value, said logic gate performing a logical operation upon an output of said delay element,
said control circuit controlling an operation of said logic gate and said digital value on the basis of a phase difference between the output of said delay element and a reference clock signal; and
a frequency divider circuit for frequency-dividing said output clock signal,
wherein either or both of a division ratio in said frequency divider circuit and a multiplication ratio in said multiplier circuit are controlled based on said digital value.

12. A clock generation system comprising:
a clock generation circuit including a voltage-controlled oscillator, a phase comparator and a loop filter,
an oscillation frequency in said voltage-controlled oscillator being controlled based on a control voltage,
said phase comparator comparing phases of a reference clock signal and a frequency-divided clock that is obtained by frequency dividing an output of said voltage-controlled oscillator,
said loop filter outputting said control voltage on the basis of an output of said phase comparator; and
a power supplier for supplying operating power to said clock generation circuit,
wherein a parameter of said operating power is controlled based on a value of said control voltage.

13. The clock generation system according to claim 12, further comprising:
a storage for storing a parameter of said operating power.

14. The clock generation system according to claim 12, further comprising:
a CPU for controlling a parameter of said operating power on the basis of said control voltage.

15. The clock generation system according to claim 14, wherein
said clock generation circuit, said power supplier and said CPU respectively include a plurality of clock generation circuits, a plurality of power suppliers and a plurality of CPUs,
said clock generation system further comprising:
a bus for interconnecting said plurality of CPUs, said plurality of clock generation circuits and said plurality of power suppliers.

16. A clock generation system comprising:
a clock generation circuit including:
a voltage-controlled oscillator in which an oscillation frequency is controlled based on a control voltage;
a phase comparator for comparing phases of a reference clock signal and a frequency-divided clock which is obtained by frequency dividing an output of said voltage-controlled oscillator; and
a loop filter for outputting said control voltage on the basis of an output of said phase comparator,
said clock generation system generating an output clock signal having a frequency which is controlled based on said control voltage.

17. The clock generation system according to claim 16, further comprising:
a storage for storing a frequency control signal which is obtained based on said control voltage and which controls said frequency of said output clock signal.

18. The clock generation system according to claim 16, further comprising:
a CPU for controlling said frequency of said output clock signal on the basis of said control voltage.

19. The clock generation system according to claim 18, wherein
said clock generation circuit and said CPU respectively include a plurality of clock generation circuits and a plurality of CPUs,
said clock generation system further comprising:
a bus for interconnecting said plurality of CPUs and said plurality of clock generation circuits.

20. A clock generation system comprising:
an analog PLL circuit including a voltage-controlled oscillator, a phase comparator and a loop filter,
an oscillation frequency in said voltage-controlled oscillator being controlled based on a control voltage;
said phase comparator comparing phases of a reference clock signal and a frequency-divided clock which is obtained by frequency-dividing an output of said voltage-controlled oscillator,
said loop filter outputting said control voltage on the basis of an output of said phase comparator; and
a frequency divider circuit for frequency-dividing an output of said voltage-controlled oscillator,
wherein either or both of a division ratio in said frequency divider circuit and a division ratio in said analog PLL circuit are controlled based on said control voltage.
